(19) United States
(12) Patent Application Publication
(10) Pub. No.: US 2019/0369497 A1
(43) Pub. Date: Dec. 5, 2019

(54) PHOTOSENSITIVE COMPOSITION, CURED FILM, COLOR FILTER, SOLID-STATE IMAGING ELEMENT AND IMAGE DISPLAY DEVICE

(71) Applicant: FUJIFILM Corporation, Tokyo (JP)

(72) Inventors: Masahiro MORI, Haibara-gun (JP); Akio Mizuno, Haibara-gun (JP); Kazuya Oota, Haibara-gun (JP)

(73) Assignee: FUJIFILM Corporation, Tokyo (JP)

(21) Appl. No.: 16/454,650

(22) Filed: Jun. 27, 2019

Related U.S. Application Data
(63) Continuation of application No. PCT/JP2018/003007, filed on Jan. 30, 2018.

(30) Foreign Application Priority Data
Feb. 23, 2017 (JP) 2017-032489

(51) Int. Cl. G03F 7/033; G03F 7/028; G03F 7/20; C08G 81/02

(52) U.S. Cl. CPC G03F 7/033; G03F 7/028; C08G 81/027; C08G 81/025; G03F 7/20

(57) ABSTRACT

Provided are a photosensitive composition capable of forming a cured film having suppressed color unevenness, a cured film, a color filter, a solid-state imaging element, and an image display device. The photosensitive composition includes a compound having an ethylenically unsaturated group, a color material, and a photopolymerization initiator, in which a content of the color material is 50% by mass or more with respect to the total solid content of the photosensitive composition, and a content of a compound with a weight-average molecular weight of 3,000 or more having an ethylenically unsaturated group in the total mass of the compound having an ethylenically unsaturated group is 70% by mass or more.

### CROSS-REFERENCE TO RELATED APPLICATIONS

This application is a Continuation of PCT International Application No. PCT/JP2018/003007 filed on Jan. 30, 2018, which claims priority under 35 U.S.C § 119(a) to Japanese Patent Application No. 2017-032489 filed Feb. 23, 2017. Each of the above application(s) is hereby expressly incorporated by reference, in its entirety, into the present application.

### BACKGROUND OF THE INVENTION

### 1. Field of the Invention

The present invention relates to a photosensitive composition. More specifically, the present invention relates to a photosensitive composition including a color material. The present invention further relates to a cured film, a color filter, a solid-state imaging element, and an image display device, each of which uses the photosensitive composition.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

A color filter has been produced using a photosensitive composition including a compound having an ethylenically unsaturated group, a color material, and a photopolymerization initiator, or the like (see JP2010-070601A and JP2012-173635A).

### SUMMARY OF THE INVENTION

According to the studies conducted by the present inventors, it was found that color unevenness is easily generated in a cured film thus formed, by increasing the concentration of a color material in a solid content with respect to a photosensitive composition including a compound having an ethylenically unsaturated group, a color material, and a photopolymerization initiator.

Therefore, an object of the present invention is to provide a photosensitive composition capable of forming a cured film having suppressed color unevenness, a cured film, a color filter, a solid-state imaging element, and an image display device.

According to the studies conducted by the present inventors, it was found that a photosensitive composition as described later is capable of forming a cured film having suppressed color unevenness, thereby leading to completion of the present invention. The present invention provides the following aspects.

<1> A photosensitive composition comprising:

a compound having an ethylenically unsaturated group;

a color material; and

a photopolymerization initiator,

in which a content of the color material is 50% by mass or more with respect to the total solid content of the photosensitive composition, and

a content of a compound A with a weight-average molecular weight of 3,000 or more having an ethylenically unsaturated group in the total mass of the compound having an ethylenically unsaturated group is 70% by mass or more.

<2> The photosensitive composition as described in <1>,

in which a content of the compound A in the total mass of the compound having an ethylenically unsaturated group is 90% by mass or more.

<3> The photosensitive composition as described in <1> or <2>.

in which the compound A includes a repeating unit having an ethylenically unsaturated group in a side chain.

<4> The photosensitive composition as described in <3>,

in which the repeating unit having an ethylenically unsaturated group in a side chain has at least one group selected from a vinyl group, a vinyloxy group, an allyl group, a methallyl group, a (meth)acryloyl group, a styryl group, a cinnamoyl group, or a maleimido group in a side chain.

<5> The photosensitive composition as described in any one of <1> to <4>.

in which the compound A further includes a repeating unit having a graft chain.

<6> The photosensitive composition as described in <5>,

in which the graft chain includes at least one structure selected from a polyester structure, a polyether structure, a poly(meth)acryl structure, a polyurethane structure, a polyurea structure, or a polyamide structure.

<7> The photosensitive composition as described in <5>,

in which the graft chain includes a polyester structure.

<8> The photosensitive composition as described in any one of <5> to <7>,

in which the weight-average molecular weight of the repeating unit having a graft chain is 1,000 or more.

<9> The photosensitive composition as described in any one of <1> to <8>,

in which the compound A includes a repeating unit having an ethylenically unsaturated group and a repeating unit having a graft chain.

<10> The photosensitive composition as described in any one of <1> to <9>,

in which the compound A includes a repeating unit represented by Formula (A-1-1) and a repeating unit represented by Formula (A-1-2),

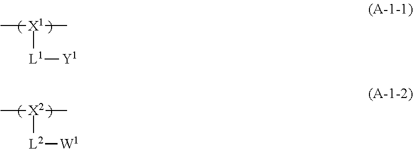

in Formula (A-1-1), X¹ represents a main chain of the repeating unit, L¹ represents a single bond or a divalent linking group, and Y¹ represents a group including an ethylenically unsaturated group, and

in Formula (A-1-2), X² represents a main chain of the repeating unit, L² represents a single bond or a divalent linking group, and W¹ represents a graft chain.

<11> The photosensitive composition as described in <9> or <10>,

in which the compound A further includes a repeating unit having an acid group.

<12> The photosensitive composition as described in any one of <1> to <11>,

in which an amount of the ethylenically unsaturated group of the compound A is 0.2 to 5.0 mmol/g.

<13> The photosensitive composition as described in any one of <1> to <12>,

in which an acid value of the compound A is 20 to 150 mgKOH/g.

<14> A cured film obtained from the photosensitive composition as described in any one of <1> to <13>.

<15> A color filter comprising the cured film as described in <14>.

<16> A solid-state imaging element comprising the cured film as described in <14>.

<17> An image display device comprising the cured film as described in <14>.

According to the present invention, it is possible to provide a photosensitive composition capable of forming a cured film having suppressed color unevenness. It is also possible to form a cured film having suppressed color unevenness, a color filter, a solid-state imaging element, and an image display device.

### DESCRIPTION OF THE PREFERRED EMBODIMENTS

Hereinafter, the contents of the present invention will be described in detail.

In citations for a group (atomic group) in the present specification, in a case where the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

In the present specification. “exposure” includes, unless otherwise specified, not only exposure using light but also lithography using particle rays such as electron beams and ion beams. In addition, examples of light used for the exposure generally include actinic rays or radiation such as a bright line spectrum of a mercury lamp, far ultraviolet rays typified by an excimer laser, extreme ultraviolet rays (EUV light), X-rays, electron beams, or the like.

In the present specification, a numerical range expressed using “to” means a range that includes the preceding and succeeding numerical values of “to” as the lower limit value and the upper limit value, respectively.

In the present specification, the total solid content refers to a total amount of the components other than a solvent from all the components of a composition.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, a term “step” not only means an independent step, but also includes a step which is not clearly distinguished from other steps in a case where an intended action of the step is obtained.

In the present specification, a weight-average molecular weight (Mw) and a number-average molecular weight (Mn) are each defined as a value in terms of polystyrene through measurement by means of gel permeation chromatography (GPC).

<Photosensitive Composition>

The photosensitive composition of an embodiment of the present invention is a photosensitive composition including a compound having an ethylenically unsaturated group, a color material, and a photopolymerization initiator, in which a content of the color material is 500/by mass or more with respect to the total solid content of the photosensitive composition, and a content of a compound A with a weight-average molecular weight of 3,000 or more having an ethylenically unsaturated group is 70% by mass or more.

With the photosensitive composition of the embodiment of the present invention, it is possible to form a cured film having suppressed color unevenness. A reason why such an effect is obtained is presumed as follows. It is presumed that the ethylenically unsaturated bond group of the compound having an ethylenically unsaturated group in the photosensitive composition interacts with the color material such that the color material and the compound having an ethylenically unsaturated group are adjacent to each other. It is presumed that since the photosensitive composition of the embodiment of the present invention includes a compound A with a weight-average molecular weight of 3.000 or more having an ethylenically unsaturated group as the compound having an ethylenically unsaturated group and the content of the compound A in the total mass of the compound having an ethylenically unsaturated group is 70% by mass or more, the compound A is present in the vicinity of the color material. That is, it is presumed that the color material is present in the photosensitive composition so that it may be surrounded by the compound A. It is presumed that since the compound A is a compound with a high molecular weight, the compound A is present in the vicinity of the color material, and thus, aggregation among the color materials is suppressed. In addition, it is presumed that by curing the compound A in the vicinity of the color material, aggregation of the color material in the film is suppressed, and as a result, a cured film having suppressed color unevenness could be formed.

Furthermore, since the photosensitive composition of the embodiment of the present invention has a content of the color material of 50% by mass or more with respect to the total solid content of the photosensitive composition, it is possible to reduce a film thickness while maintaining desired spectral characteristics. As a result, it is possible to reduce the height of a color filter or the like.

Hereinafter, the respective components that can constitute the photosensitive composition of the embodiment of the present invention will be described.

<<Color Material>>

The photosensitive composition of the embodiment of the present invention contains a color material. In the present invention, the color material may be either a pigment or a dye. The color material used in the present invention preferably includes the pigment. Further, a content of the pigment in the color material is preferably 50% by mass or more, more preferably 70% by mass or more, still more preferably 80% by mass or more, and particularly preferably 90% by mass or more. In addition, the color material may be only constituted with the pigment.

Examples of the pigment include an inorganic pigment and an organic pigment, with the organic pigment being preferable. The average particle diameter of the pigment is preferably 20 to 300 nm, more preferably 25 to 250 nm, and still more preferably 30 to 200 nm. The “average particle diameter” as mentioned herein means an average particle diameter for secondary particles formed by aggregation of primary particles of a pigment. Further, the particle size distribution (hereinafter simply also referred to as a “particle size distribution”) of the secondary particles of a pigment that can be used is preferably a particle size distribution such that secondary particles falling within (average particle diameter±100) nm accounts for 70% by mass or more, and preferably 80% by mass or more of all the particles. In addition, the particle size distribution of the secondary particles can be measured using a scattering intensity distribution. In addition, the average particle diameter of the primary particles can be determined by measuring the particle sizes of 100 particles in an area in which particles are not aggregated by observation with a scanning electron microscope (SEM) or a transmission electron microscope (TEM) and calculating an average value thereof.

Specific examples of the organic pigment include pigments shown below. The organic pigments shown below may be used singly or in combination of two or more kinds thereof.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like (all yellow pigments);

C. I. Pigment Orange 2, 5, 13, 16, 17:1, 31, 34, 36, 38, 43, 46, 48, 49, 51, 52, 55, 59, 60, 61, 62, 64, 71, 73, and the like (all orange pigments):

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, and the like (all red pigments);

C. I. Pigment Green 7, 10, 36, 37, 58, 59, and the like (all green pigments);

C. I. Pigment Violet 1, 19, 23, 27, 32, 37, 42, and the like (all violet pigments);

C. I. Pigment Blue 1, 2, 15, 15:1, 15:2, 15:3, 15:4, 15:6, 16, 22, 60, 64, 66, 79, 80, and the like (all blue pigments).

Furthermore, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A.

In addition, an aluminumphthalocyanine compound having a phosphorus atom can also be used as the blue pigment. Specific examples thereof include the compounds described in paragraphs 0022 to 0030 of JP2012-247591A and paragraph 0047 of JP2011-157478A.

The dye is not particularly limited and known dyes can be used. As chemical structures thereof, a pyrazolazo-based dye, an anilinoazo-based dye, a triarylmethane-based dye, an anthraquinone-based dye, an anthrapyridone-based dye, a benzylidene-based dye, an oxonol-based dye, a pyrazolotriazolazo-based dye, a pyridonazo-based dye, a cyanine-based dye, a phenothiazine-based dye, a pyrrolopyrazolazomethine-based dye, a xanthene-based dye, a phthalocyanine-based dye, a benzopyran-based dye, an indigo-based dye, a pyromethane-based dye, or the like can be used. Further, the thiazole compounds described in JP2012-158649A, the azo compound described in JP2011-184493A, or the azo compound described in JP2011-145540A can also be preferably used. Furthermore, the quinophthalone compounds described in paragraph Nos. 0011 to 0034 of JP2013-054339A, the quinophthalone compounds described in paragraph Nos. 0013 to 0058 of JP2014-026228A, or the like can be used as the yellow dyes.

In the present invention, a dye multimer can be used as the color material. The dye multimer is preferably a dye that is used after being dissolved in a solvent, but the dye multimer may form a particle. In a case where the dye multimer is the particle, it is usually used in a state of being dispersed in a solvent. The dye multimer in the particle state can be obtained by, for example, emulsion polymerization, and specific examples thereof include the compounds and production methods described in JP2015-214682A. The dye multimer has 2 or more dye structures, and preferably 3 or more dye structures in one molecule. The upper limit is particularly not limited, but can be 100 or less. The dye structures contained in one molecule may be the same dye structures or different dye structures.

The weight-average molecular weight (Mw) of the dye multimer is preferably 2,000 to 50,000. The lower limit is more preferably 3,000 or more, and still more preferably 6,000 or more. The upper limit is more preferably 30,000 or less, and still more preferably 20,000 or less.

The dye structure that the dye multimer has may be a structure derived from a dye compound having absorption in the visible region (preferably at a wavelength in the range of 400 to 700 nm, and more preferably at a wavelength in the range of 400 to 650 nm). Examples thereof include a triaryl methane dye structure, a xanthene dye structure, an anthraquinone dye structure, a cyanine dye structure, a squarylium dye structure, a quinophthalone dye structure, a phthalocyanine dye structure, a subphthalocyanine dye structure, an azo dye structure, a pyrazolotriazole dye structure, a dipyromethane dye structure, an isoindoline dye structure, a thiazole dye structure, a benzimidazolone dye structure, a perinone dye structure, a pyrrolopyrrole dye structure, a diketopyrrolopyrrole dye structure, a diimmonium dye structure, a naphthalocyanine dye structure, a rylene dye structure, a dibenzofuranone dye structure, a merocyanine dye structure, a croconium dye structure, and an oxonol dye structure.

It is preferable that the dye multimer includes at least one of a repeating unit represented by Formula (A), a repeating unit represented by Formula (B), or a repeating unit represented by Formula (C), or is represented by Formula (D).

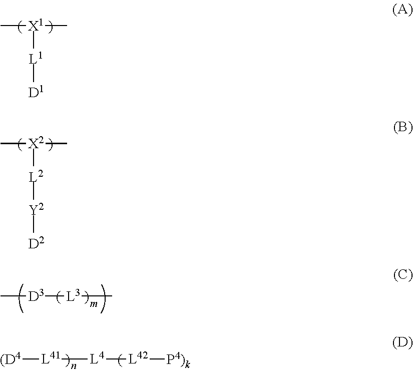

In Formula (A), X¹ represents the main chain of the repeating unit, L¹ represents a single bond or a divalent linking group, and D¹ represents a dye structure. With regard to the details of Formula (A), reference can be made to paragraphs 0138 to 0152 of JP2013-029760A, the contents of which are incorporated herein by reference.

In Formula (B), X² represents the main chain of the repeating unit, L² represents a single bond or a divalent linking group, D² represents a dye structure having a group that can be bonded to Y² by an ion bond or a coordination bond, and Y² represents a group that can be bonded to D² by an ion bond or a coordination bond. With regard to the details of Formula (B), reference can be made to paragraphs 0156 to 0161 of JP2013-029760A, the contents of which are incorporated herein by reference.

In Formula (C). L³ represents a single bond or a divalent linking group, D³ represents a dye structure, and m represents 0 or 1. With regard to the details of Formula (C), reference can be made to paragraphs 0165 to 0167 of JP2013-029760A, the contents of which are incorporated herein by reference.

In Formula (D), L⁴ represents an (n+k)-valent linking group, L⁴¹ and L⁴² each independently represent a single bond or a divalent linking group, D⁴ represents a dye structure, and P⁴ represents a substituent; and n represents 2 to 15, k represents 0 to 13, and n+k represents 2 to 15. In a case where n is 2 or more, a plurality of D⁴'s may be the same as or different from each other. In a case where k is 2 or more, a plurality of P⁴'s may be the same as or different from each other.

Examples of the (n+k)-valent linking group represented by L⁴ include the linking group described in paragraph Nos. 0071 to 0072 of JP2008-222950A, and the linking group described in paragraph No. 0176 of JP2013-029760A.

Examples of the substituent represented by P⁴ include an acid group and a curable group. Examples of the curable group include a radically polymerizable group such as a group having an ethylenically unsaturated bond, an epoxy group, an oxazoline group, and a methylol group. Examples of the group having an ethylenically unsaturated bond include a vinyl group, a (meth)allyl group, and a (meth)acryloyl group. Examples of the acid group include a carboxyl group, a sulfonic acid group, and a phosphoric acid group. The substituent represented by P⁴ may be a monovalent polymer chain having a repeating unit. The monovalent polymer chain having a repeating unit is preferably a monovalent polymer chain having a repeating unit derived from a vinyl compound.

The dye structure represented by D⁴ is a structure formed by removing any of one or more atoms contained in the dye compound, or formed by the bonding of a part of the dye compound to L⁴¹. Further, the dye structure may be a polymer chain including a repeating unit having a dye structure (structure formed by removing any of one or more atoms contained in the dye compound) in the main chain or side chain. The polymer chain may include a dye structure, and it is not particularly determined, but is preferably one selected from a (meth)acryl-based resin, a styrene-based resin, and a (meth)acryl/styrene-based resin. The repeating unit of the polymer chain is not particularly determined, but examples thereof include the repeating unit represented by Formula (A) and the repeating unit represented by Formula (C). In addition, the total amount of the repeating units having a dye structure out of all the repeating units constituting the polymer chain is preferably 5% to 60% by mole, more preferably 10% to 50% by mole, and still more preferably 20% to 40% by mole.

The dye multimer represented by Formula (D) is preferably a structure represented by Formula (D-1).

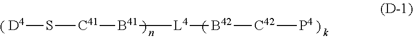

In Formula (D-1), L⁴ represents an (n+k)-valent linking group. n represents 2 to 15, and k represents 0 to 13. D⁴ represents a dye structure, and P⁴ represents a substituent. B⁴¹ and B⁴² each independently represent a single bond, —O—, —S—, —CO—, —NR—, —O₂C—, —CO₂—, —NROC—, or —CONR—. R represents a hydrogen atom, an alkyl group, or an aryl group. C⁴¹ and C⁴² each independently represent a single bond or a divalent linking group. S represents a sulfur atom. In a case where n is 2 or more, a plurality of D⁴'s may be the same as or different from each other. In a case where k is 2 or more, a plurality of P⁴'s may be the same as or different from each other. n+k represents 2 to 15.

L⁴, D⁴, and P⁴ in Formula (D-1) have the same definitions as L⁴, D⁴, and P⁴ in Formula (D).

B⁴¹ and B⁴² in Formula (D-1) are each preferably a single bond, —O—, —CO—, —O₂C—, —CO₂—, —NROC—, or —CONR—, and more preferably a single bond, —O—, —CO—, —O₂C—, or —CO₂—. R represents a hydrogen atom, an alkyl group, or an aryl group.

C⁴¹ and C⁴² in Formula (D-1) each independently represent a single bond or a divalent linking group. As the divalent linking group, an alkylene group, an arylene group, and a group formed by combination of these groups are preferable. The alkylene group preferably has 1 to 30 carbon atoms, and more preferably has 1 to 10 carbon atoms. The alkylene group may be linear, branched, or cyclic. The arylene group preferably has 6 to 30 carbon atoms, and more preferably has 6 to 12 carbon atoms.

As the dye multimer, the compounds described in JP2011-213925A, JP2013-041097A, JP2015-028144A, JP2015-030742A, or the like can be used.

The content of the color material is 50% by mass or more, preferably 55% by mass or more, and more preferably 60% by mass or more, with respect to the total solid content of the photosensitive composition. The upper limit can be set to 80% by mass or less.

Furthermore, in a case where the content of a red color material in the total amount of the color material is 60% by mass or more, it is more preferable that a yellow color material is further included, and in a case where the total amount of the red color material and the yellow color material is 80% by mass or more, the color material can be preferably used as a photosensitive composition for forming a red coloring layer. Further, in a case where the content of a green color material in the total amount of the color material is 60% by mass or more, it is more preferable that a yellow color material is further included, and in a case where the total amount of the green color material and the yellow color material is 80% by mass or more, the color material can be preferably used as a photosensitive composition for forming a green coloring layer.

In addition, in a case where the content of a blue color material in the total amount of the color material is 60% by mass or more, it is more preferable that a violet color material is further included, and in a case where the total amount of the blue color material and the violet color material is 80% by mass or more, the color material can be preferably used as a photosensitive composition for forming a blue coloring layer.

<<Compound Having Ethylenically Unsaturated Group>>

The photosensitive composition of the embodiment of the present invention contains a compound having an ethylenically unsaturated group. The content of the compound A with a weight-average molecular weight of 3.000 or more having an ethylenically unsaturated group (hereinafter also referred to as a compound A) in the total mass of the compound having an ethylenically unsaturated group is 70% by mass or more, preferably 80% by mass or more, more preferably 85% by mass or more, and still more preferably 90% by mass or more. Further, the compound having an ethylenically unsaturated group used in the photosensitive composition of the embodiment of the present invention may include substantially only the compound A. An expression that the compound having an ethylenically unsaturated group includes substantially only the substantially compound A means that the content of the compound A in the total mass of the compound having an ethylenically unsaturated group is 99% by mass or more, and the content of the compound A is more preferably 99.5% by mass or more, and still more preferably includes only the compound A.

(Compound A)

The weight-average molecular weight of the compound is 3,000 or more, preferably 3,000 to 50,000, more preferably 7,000 to 40,000, and still more preferably 10,000 to 30,000. In a case where the weight-average molecular weight of the compound A is 3.000 or more, the dispersibility of the color material and the like is good, and a cured film having suppressed color unevenness is easily obtained. In the present invention, the compound A can be used as the dispersant.

Examples of the ethylenically unsaturated group contained in the compound A include a vinyl group, a vinyloxy group, an allyl group, a methallyl group, a (meth)acryloyl group, a styryl group, a cinnamoyl group, and a maleimido group, the (meth)acryloyl group, the styryl group, or the maleimido group is preferable, the (meth)acryloyl group is more preferable, and the acryloyl group is particularly preferable. Since the (meth)acryloyl group has particularly excellent reactivity and less steric hindrance, it is easily cured in the vicinity of the color material and the effects of the present invention are more remarkably obtained.

The amount of the ethylenically unsaturated group of the compound A (hereinafter also referred to as a C═C value) is preferably 0.2 to 5.0 mmol/g. The upper limit is more preferably 4.0 mmol/g or less, and still more preferably 3.0 mmol/g or less. The lower limit is more preferably 0.3 mmol/g or more. The C═C value of the compound A is a numerical value which represents a molar amount of the C═C group per gram of a solid content of the compound A. The C═C value of the compound A can be calculated using the following formula by extracting a low-molecular-weight component (a) at a C═C group site from the compound A (for example, methacrylic acid in P-1 and acrylic acid in P-2, as described later) by an alkali treatment, and measuring a content thereof by high performance liquid chromatography (HPLC). Further, in a case where the C═C group site cannot be extracted from the compound A by an alkali treatment, a value measured with a nuclear magnetic resonance (NMR) method is used.

C═C value of compound A [mmol/g]=(content [ppm] of low-molecular-weight component (a)/molecular weight [g/mol] of low-molecular-weight component (a))/(weighing value [g] of compound A×(concentration [% by mass] of solid content of compound A/100)×10)

The compound A preferably includes a repeating unit having an ethylenically unsaturated group in a side chain, and more preferably includes a repeating unit represented by Formula (A-1-1). Further, in the compound A, the repeating unit having an ethylenically unsaturated group is preferably contained in the amount of 10% by mole or more in all the repeating units of the compound A, more preferably contained in the amount of 10% to 80% by mole, and still more preferably contained in the amount of 20% to 70% by mole.

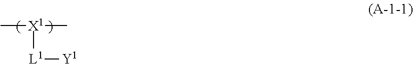

In Formula (A-1-1), X¹ represents a main chain of the repeating unit, L¹ represents a single bond or a divalent linking group, and Y¹ represents a group having an ethylenically unsaturated group.

In Formula (A-1-1), the main chain of the repeating unit represented by X¹ is not particularly limited. It is not particularly limited as long as it is a linking group formed from known polymerizable monomers. Examples thereof include a poly(meth)acryl-based linking group, a polyalkylenimine-based linking group, a polyester-based linking group, a polyurethane-based linking group, a polyurea-based linking group, a polyamide-based linking group, a polyether-based linking group, and a polystyrene-based linking group, and from the viewpoints of availability of materials for raw materials or production suitability, the poly(meth)acryl-based linking group or the polyalkylenimine-based linking group is preferable, and the (meth)acryl-based linking group is more preferable.

In Formula (A-1-1), examples of the divalent linking group represented by L¹ include an alkylene group (preferably an alkylene group having 1 to 12 carbon atoms), an alkyleneoxy group (preferably an alkyleneoxy group having 1 to 12 carbon atoms), an oxyalkylenecarbonyl group (preferably an oxyalkylenecarbonyl group having 1 to 12 carbon atoms), an arylene group (preferably an arylene group having 6 to 20 carbon atoms). —NH—, —SO—, —SO₂—, —CO—, —O—, —COO—, —OCO—, —S—, and a group formed by combination of two or more of these groups. The alkylene group, the alkylene group in the alkyleneoxy group, or the alkylene group in the oxyalkylenecarbonyl group may be any of linear, branched, and cyclic forms, and is preferably linear or branched. Further, the alkylene group, the alkylene group in the alkyleneoxy group, or the alkylene group in the oxyalkylenecarbonyl group may have a substituent or may be unsubstituted. Examples of the substituent include a hydroxyl group and an alkoxy group, and from the viewpoint of production suitability, the hydroxyl group is preferable.

In Formula (A-1-1), examples of a group having an ethylenically unsaturated group represented by Y¹ include a group including at least one selected from a vinyl group, a vinyloxy group, an allyl group, a methallyl group, a (meth)acryloyl group, a styryl group, a cinnamoyl group, or a maleimido group, the (meth)acryloyl group, the styryl group, or the maleimido group is preferable, the (meth)acryloyl group is more preferable, and the acryloyl group is still more preferable.

Specific examples of the repeating unit represented by Formula (A-1-1) include repeating units represented by Formula (A-1-1a) and Formula (A-1-1b).

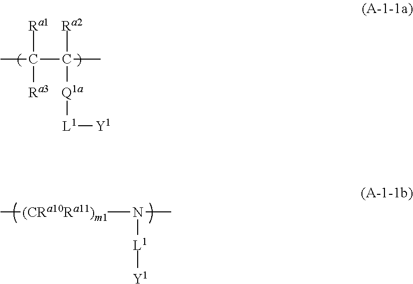

In Formula (A-1-1a), R^{a1} to R each independently represent a hydrogen atom or an alkyl group, Q^{1a} represents —CO—, —COO—, —OCO—, —CONH—, or a phenylene group, L¹ represents a single bond or a divalent linking group, Y¹ represents a group having an ethylenically unsaturated group that is radically polymerizable. The number of carbon atoms of the alkyl group represented by R^{a1} to R^{a3} is preferably 1 to 10, more preferably 1 to 3, and still more preferably 1. Q^{1a} is preferably —COO— or —CONH—, and more preferably —COO—.

In Formula (A-1-1b), R^{a10} and R^{a11} each independently represent a hydrogen atom or an alkyl group, m1 represents an integer of 1 to 5, L¹ represents a single bond or a divalent linking group, and Y¹ represents a group having an ethylenically unsaturated group that is radically polymerizable. The number of carbon atoms of the alkyl group represented by each of R^{a10} and R^{a11} is preferably 1 to 10, and more preferably 1 to 3.

It is preferable that the compound A further includes a repeating unit having a graft chain. By incorporation of the repeating unit having a graft chain into the compound A, it is possible to more effectively suppress aggregation of color materials by steric hindrance by a graft chain, and the like. The compound A preferably contains the repeating unit having a graft chain in the amount of 1.0% to 60% by mole, and more preferably contains the repeating unit having a graft chain in the amount of 1.5% to 50% by mole, in all the repeating units of the compound A.

In the present invention, the graft chain in the compound A means a polymer chain branched from the main chain of the repeating unit. The length of the graft chain is not particularly limited, and in a case % here the graft chain gets longer, a steric repulsion effect is enhanced, and thus, the dispersibility of a color material or the like can be increased. In the graft chain, the number of atoms excluding the hydrogen atoms is preferably 40 to 10,000, the number of atoms excluding the hydrogen atoms is more preferably 50 to 2,000, and the number of atoms excluding the hydrogen atoms is still more preferably 60 to 500.

The graft chain preferably includes at least one structure selected from a polyester structure, a polyether structure, a poly(meth)acryl structure, a polyurethane structure, a polyurea structure, or a polyamide structure, more preferably includes at least one structure selected from a polyester structure, a polyether structure, or a poly(meth)acryl structure, and still more preferably includes a polyester structure. Examples of the polyester structure include a structure represented by Formula (G-1), Formula (G-4), or Formula (G-5). Further, examples of the polyether structure include a structure represented by Formula (G-2). In addition, examples of the poly(meth)acryl structure include a structure represented by Formula (G-3).

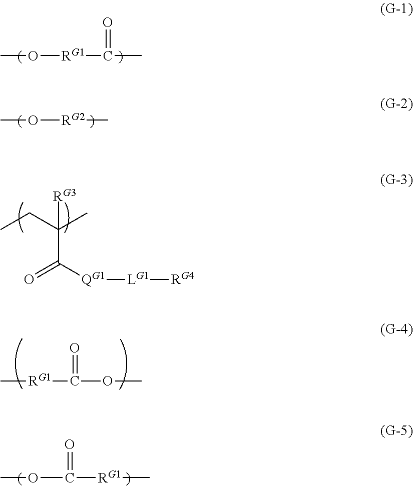

In the formulae, R^{G1} and R^{G2} each represent an alkylene group. The alkylene group represented by each of R^{G1} and R^{G2} is not particularly limited, but a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable.

In the formulae, R^{G3} represents a hydrogen atom or a methyl group.

In the formulae, Q^{G1} represents —O— or —NH—, L^{G1} represents a single bond or a divalent linking group. Examples of the divalent linking group include an alkylene group (preferably an alkylene group having 1 to 12 carbon atoms), an alkyleneoxy group (preferably an alkyleneoxy group having 1 to 12 carbon atoms), an oxyalkylenecarbonyl group (preferably an oxyalkylenecarbonyl group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by combination of two or more of these groups.

R^{G4} represents a hydrogen atom or a substituent. Examples of the substituent include an alkyl group, an aryl group, a heteroaryl group, an alkoxy group, an aryloxy group, a heteroaryloxy group, an alkylthioether group, an arylthioether group, and a heteroarylthioether group.

For example, in a case where the graft chain includes a polyester structure, the graft chain may include only one kind of the polyester structure or two or more kinds of the polyester structures having different R^{G1}'s. Further, in a case where the graft chain includes a polyether structure, the graft chain may include only one kind of the polyether structure or two or more kinds of the polyether structures having different R^{G2}'s. In addition, in a case where the graft chain includes a poly(meth)acryl structure, the graft chain may include only one kind of the poly(meth)acryl structure or two or more kinds of the poly(meth)acryl structures that are different in at least one selected from R^{G3}, Q^{G1}, L^{G1}, or R^{G4}.

The terminal structure of the graft chain may be a hydrogen atom or a substituent. Examples of the substituent include an alkyl group, an aryl group, a heteroaryl group, an alkoxy group, an aryloxy group, a heteroaryloxy group, an alkylthioether group, an arylthioether group, and a heteroarylthioether group. Among those, from the viewpoint of improvement of the dispersibility of the color material or the like, a group having a steric repulsion effect is preferable, and an alkyl group or alkoxy group having 5 to 24 carbon atoms is preferable. The alkyl group and the alkoxy group may be any of linear, branched, and cyclic forms, and are preferably linear or branched.

In the present invention, a structure represented by Formula (G-1a), Formula (G-2a), Formula (G-3a). Formula (G-4a) or Formula (G-5a) is preferable as the graft chain.

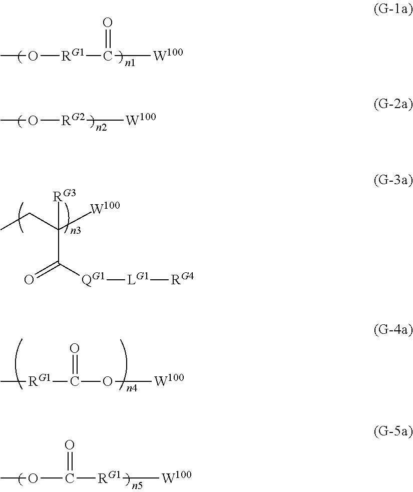

In the formulae, R^{G1} and R^{G2} each represent an alkylene group, R^{G3} represents a hydrogen atom or a methyl group, Q^{G1} represents —O— or —NH—, L^{G1} represents a single bond or a divalent linking group, R^{G4} represents a hydrogen atom or substituent, and W¹⁰⁰ represents a hydrogen atom or a substituent. n1 to n5 each independently represent an integer of 2 or more. R^{G1} to R^{G4}, Q^{G1}, and L^{G1} have the same definitions as those of R^{G1} to R^{G4}, Q^{G1} and L^{G1} described in Formulae (G-1) to (G-5), respectively, and preferred ranges thereof are also the same.

In Formulae (G-1a) to (G-5a), W¹⁰⁰ is preferably a substituent. Examples of the substituent include an alkyl group, an aryl group, a heteroaryl group, an alkoxy group, an aryloxy group, a heteroaryloxy group, an alkylthioether group, an arylthioether group, and a heteroarylthioether group. Among those, from the viewpoint of improvement of the dispersibility of the color material or the like, a group having a steric repulsion effect is preferable, and an alkyl group or alkoxy group having 5 to 24 carbon atoms is preferable. The alkyl group and the alkoxy group may be any of linear, branched, and cyclic forms, and are preferably linear or branched.

In Formulae (G-1a) to (G-5a), n1 to n5 are each preferably an integer of 2 to 100, more preferably an integer of 2 to 80, and still more preferably an integer of 8 to 60.

Furthermore, in Formula (G-1a), R^{G1}'s in each of the repeating units in a case where n1 is 2 or more may be the same as or different from each other. In addition, in a case where two or more kinds of the repeating units having different R^{G1}'s are included, the arrangement of the respective repeating units is not particularly limited, and may be any one of random, alternate, and block arrangements, which are also the same as in Formula (G-2a) to Formula (G-5a).

Examples of the repeating unit having a graft chain include a repeating unit represented by Formula (A-1-2).

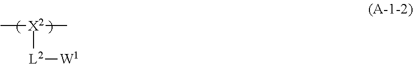

Examples of the main chain of the repeating unit represented by X² in Formula (A-1-2) include the structures described for X¹ in Formula (A-1-1), and preferred ranges thereof are also the same. Examples of the divalent linking group represented by L² in Formula (A-1-2) include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by combination of two or more of these groups. Examples of the graft chain of the represented by W¹ in Formula (A-1-2) include the above-mentioned graft chains.

Specific examples of the repeating unit represented by Formula (A-1-2) include a repeating unit represented by Formula (A-1-2a) and a repeating unit represented by Formula (A-1-2b).

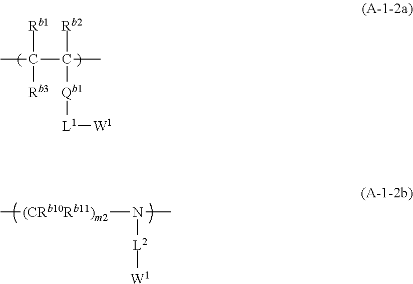

In Formula (A-1-2a), R^{b1} to R^{b3} each independently represent a hydrogen atom or an alkyl group, Q^{b1} represents —CO—, —COO—, —OCO—, —CONH—, or a phenylene group, L² represents a single bond or a divalent linking group, and W¹ represents a graft chain. The number of carbon atoms represented by each of R^{b1} to R^{b3} is preferably 1 to 10, more preferably 1 to 3, and still more preferably 1. Q^{b1} is preferably —COO— or —CONH—, and more preferably —COO—.

In Formula (A-1-2b), R^{b10} and R^{b11} each independently represent a hydrogen atom or an alkyl group, m2 represents an integer of 1 to 5. L² represents a single bond or a divalent linking group, and W¹ represents a graft chain. The number of carbon atoms represented by each of R^{b10} and R^{b11} is preferably 1 to 10, and more preferably 1 to 3.

In the compound A, the weight-average molecular weight of the repeating unit having a graft chain (Mw) is preferably 1,000 or more, more preferably 1.000 to 10,000, and still more preferably 1,000 to 7.500. Further, in the present invention, the weight-average molecular weight of the repeating unit having a graft chain is a value calculated from the raw material monomer used in the polymerization of the same repeating unit. For example, the repeating unit having a graft chain can be formed by the polymerization of macromonomers. Here, the macromonomer means a high-molecular-weight compound having a polymerizable group introduced into a terminal thereof. In a case where a repeating unit having a graft chain is formed using the macromonomers, the weight-average molecular weight of the macromonomers corresponds to the repeating unit having a graft chain.

The compound A preferably includes a repeating unit having an ethylenically unsaturated group and a repeating unit having a graft chain. Further, the compound A preferably contains 10% to 80% by mole of the repeating unit having an ethylenically unsaturated group, and more preferably contains 20% to 70% by mole of the repeating unit having an ethylenically unsaturated group in all the repeating units of the compound A. Further, the compound A preferably contains 1.0% to 60% by mole of the repeating unit having an ethylenically unsaturated group, and more preferably contains 1.5% to 50% by mole of the repeating unit having an ethylenically unsaturated group in all the repeating units of the compound A.

It is also preferable that the compound A further includes a repeating unit having an acid group. By further incorporating the repeating unit having an acid group into the compound A, the dispersibility of the color material or the like can be further improved. In addition, the developability can also be improved. Examples of the acid group include a carboxyl group, a sulfo group, and a phosphoric acid group.

Examples of the repeating unit having an acid group include a repeating unit represented by Formula (A-1-3).

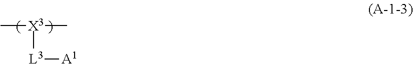

Examples of the main chain of the repeating unit represented by X³ in Formula (A-1-3) include the structures described for X¹ in Formula (A-1-1), and preferred ranges thereof are also the same.

Examples of the divalent linking group represented by L³ in Formula (A-1-3) include an alkylene group (preferably an alkylene group having 1 to 12 carbon atoms), an alkenylene group (preferably an alkenylene group having 2 to 12 carbon atoms), an alkyleneoxy group (preferably having 1 to 12 carbon atoms alkyleneoxy group), an oxyalkylenecarbonyl group (preferably an oxyalkylenecarbonyl group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by combination of two or more of these groups. The alkylene group, the alkylene group in the alkyleneoxy group, or the alkylene group in the oxyalkylenecarbonyl group may be any of linear, branched, and cyclic forms, and is preferably linear or branched. Further, the alkylene group, the alkylene group in the alkyleneoxy group, or the alkylene group in the oxyalkylenecarbonyl group may have a substituent or may be unsubstituted. Examples of the substituent include a hydroxyl group.

Examples of the acid group represented by A¹ in Formula (A-1-3) include a carboxyl group, a sulfo group, and a phosphoric acid group.

Specific examples of the repeating unit represented by Formula (A-1-3) include a repeating unit represented by Formula (A-1-3a) and a repeating unit represented by Formula (A-1-3b).

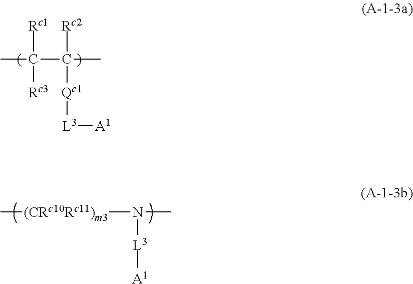

In Formula (A-1-3a), R_{c1} to R^{c3} each independently represent a hydrogen atom or an alkyl group, Q^{c1} represents —CO—, —COO—, —OCO—. —CONH—, or a phenylene group. L³ represents a single bond or a divalent linking group, and A¹ represents an acid group. The number of carbon atoms of the alkyl group represented by each of R^{c1} to R^{c3} is preferably 1 to 10, more preferably 1 to 3, and still more preferably 1. Q^{c1} is preferably —COO— or —CONH—, and more preferably —COO—.

In Formula (A-1-3b), R^{c10} and R^{c11} each independently represent a hydrogen atom or an alkyl group, m3 represents an integer of 1 to 5, L³ represents a single bond or a divalent linking group, and A¹ represents an acid group. The number of carbon atoms of the alkyl group represented by each of R^{c10} and R^{c11} is preferably 1 to 10, and more preferably 1 to 3.

As the repeating unit represented by Formula (A-1-3a), a repeating unit represented by Formula (A-1-3a-1) is more preferable.

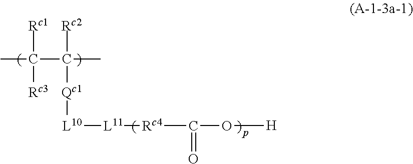

In Formula (A-1-3a-1), R^{c1} to R^{c3} each independently represent a hydrogen atom or an alkyl group, Q^{c1} represents —CO—, —COO—, —OCO—, —CONH—, or a phenylene group, L¹⁰ represents a single bond or an alkylene group, L¹¹ represents a single bond. —O—, —S—, —NH—, —CO—, —OCO—, or —COO—, R^{c4} represents an alkylene group or an arylene group, and p represents an integer of 0 to 5, provided that in a case where p is 0, L¹¹ is —COO— or L¹⁰ and L¹¹ are each a single bond and Q^{c1} is —COO—.

In Formula (A-1-3a-1), the number of carbon atoms of the alkyl group represented by each of R^{c1} to R^{c3} is preferably 1 to 10, more preferably 1 to 3, and still more preferably 1. Q^{c1} is preferably —COO— or —CONH—, and more preferably —COO—.

In Formula (A-1-3a-1), the number of carbon atoms of the alkylene group represented by L¹⁰ is preferably 1 to 10, and more preferably 1 to 5. The alkylene group may be any of linear, branched, and cyclic forms, and is preferably linear. L¹⁰ is preferably a single bond.

In Formula (A-1-3a-1), L¹¹ is preferably a single bond or —OCO—, and more preferably a single bond.

In Formula (A-1-3a-1), R^{C4} is preferably an alkylene group. The number of carbon atoms of the alkylene group is preferably 1 to 12, more preferably 1 to 8, still more preferably 2 to 8, and particularly preferably 2 to 6. The alkylene group represented by R^{c4} may be any of linear, branched, and cyclic forms, and is preferably linear or branched, and more preferably linear.

In Formula (A-1-3a-1), p represents an integer of 0 to 5, and is preferably an integer of 0 to 3, and more preferably an integer of 0 to 2.

In a case where the compound A includes a repeating unit having an acid group, the compound A preferably contains 80% by mole or less of the repeating unit having an acid group, and more preferably contains 10% to 80% by mole of the repeating unit having an acid group in all the repeating units of the compound A.

The acid value of the compound A is preferably 20 to 150 mgKOH/g. The upper limit is more preferably 100 mgKOH/g or less. The lower limit is preferably 30 mgKOH/g or more, and more preferably 35 mgKOH/g or more. In a case where the acid value of the compound A is within the range, particularly excellent dispersibility is easily obtained. In addition, excellent developability is easily obtained.

The compound A may further include other repeating units. For example, in a case where the compound A includes the above-mentioned repeating unit represented by Formula (A-1-2b) as the repeating unit having a graft chain, the compound A can further include repeating units represented by Formula (A-1-4b) and/or Formula (A-1-5b).

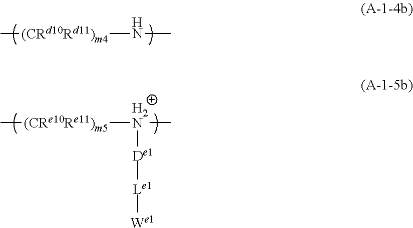

In Formula (A-1-4b), R^{d10} and Rd¹¹ each independently represent a hydrogen atom or an alkyl group, and m4 represents an integer of 1 to 5. The number of carbon atoms of the alkyl group represented by each of R^{d10} and R^{d11} is preferably 1 to 10, and more preferably 1 to 3.

In Formula (A-1-5b), R^{e10} and R^{e11} each independently represent a hydrogen atom or an alkyl group, m5 represents an integer of 1 to 5, D^{e1} represents an anion group, L^{e1} represents a single bond or a divalent linking group, and W^{e1} represents a graft chain. The number of carbon atoms of the alkyl group represented by each of R^{e10} and R^{e11} is preferably 1 to 10, and more preferably 1 to 3. Examples of the anion group represented by D^{e1} include —SO₃⁻, —COO⁻, —PO₄⁻, and —PO₄H⁻. Examples of the divalent linking group represented by L^{e1} and the graft chain represented by W^{e1} include those described for L² and W¹ in Formula (A-1-2) as described above.

Moreover, the compound A can include a repeating unit derived from a monomer component including a compound represented by General Formula (ED1) and/or a compound represented by General Formula (ED2) (these compounds are hereinafter also referred to as an “ether dimer” in some cases).

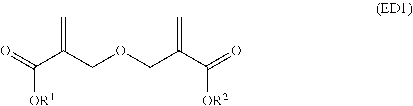

In General Formula (ED1), R¹ and R² each independently represent a hydrogen atom or a hydrocarbon group having 1 to 25 carbon atoms, which may have a substituent.

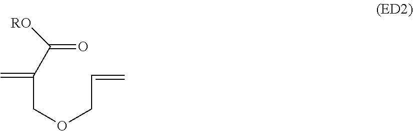

In Formula (ED2), R represents a hydrogen atom or an organic group having 1 to 30 carbon atoms. With regard to the specific examples of Formula (ED2), reference can be made to the descriptions in JP2010-168539A.

With regard to the specific examples of the ether dimer, reference can be made to paragraph No. 0317 of JP2013-029760A, the contents of which are incorporated herein by reference. The ether dimers may be used singly or in combination of two or more kinds thereof.

Specific examples of the compound A include the following compounds.

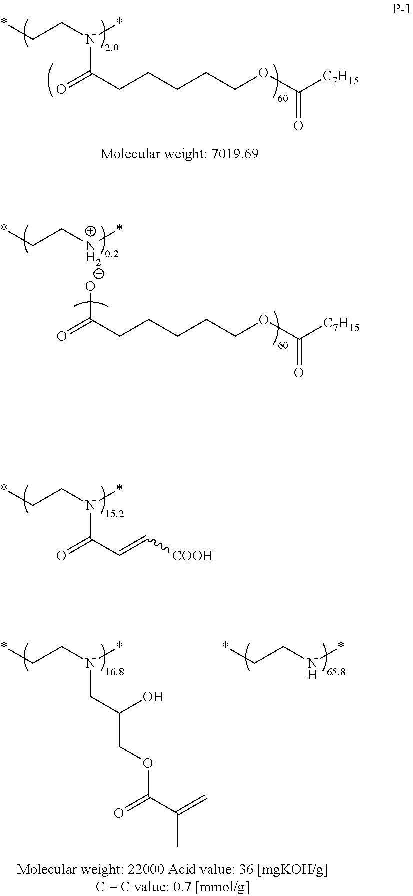

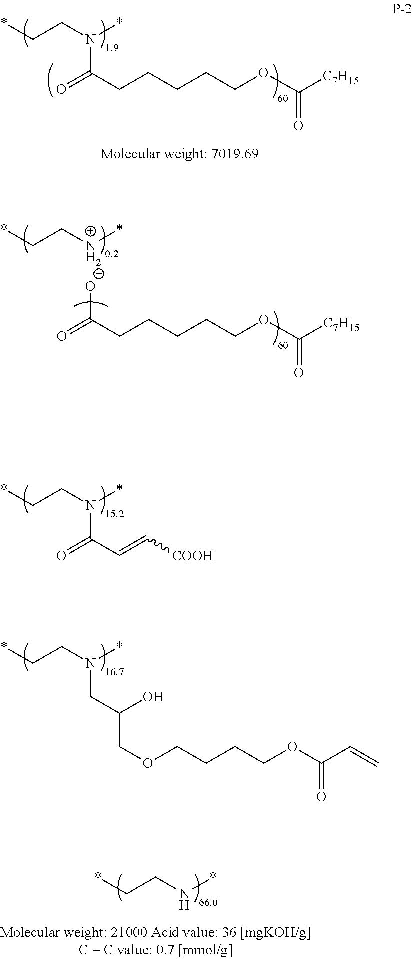

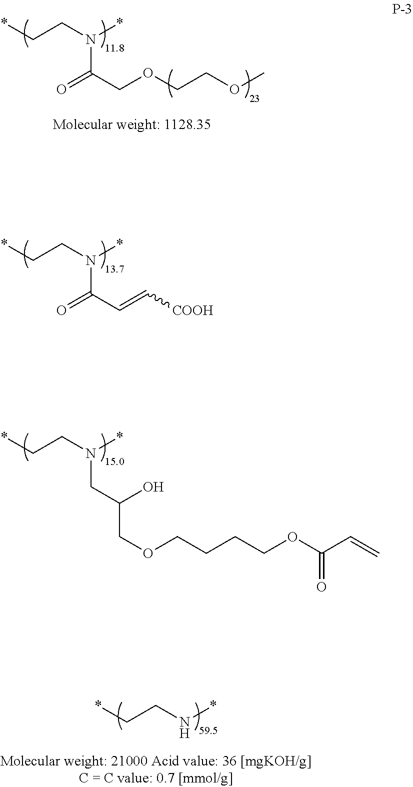

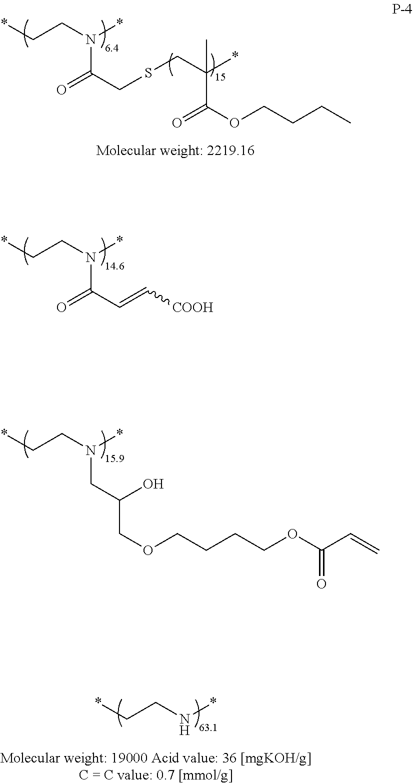

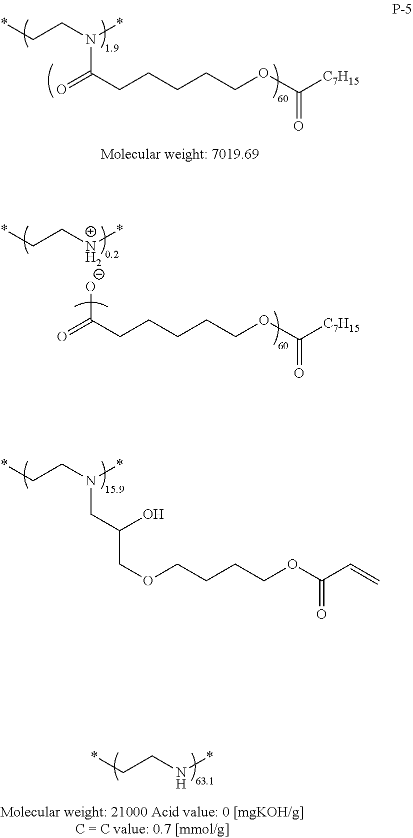

TABLE 1

| | Structure of compound A | | |
|---|---|---|---|
| | A-1-1 | | |
| | | Structure of C═C group | A-1-2 |
| P-6 | 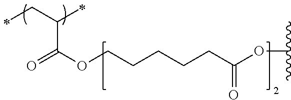 | 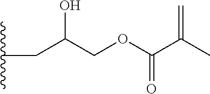 [SMILES: *CC(O)COC(=O)C(=C)C] | 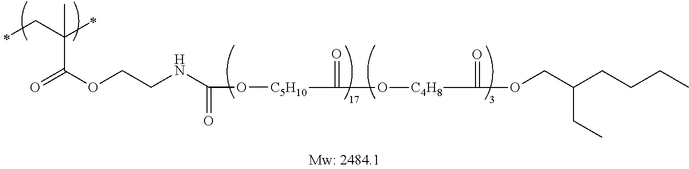 |
| P-7 | 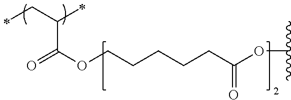 | 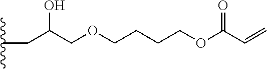 [SMILES: *CC(O)COCCCCOC(=O)C=C] | 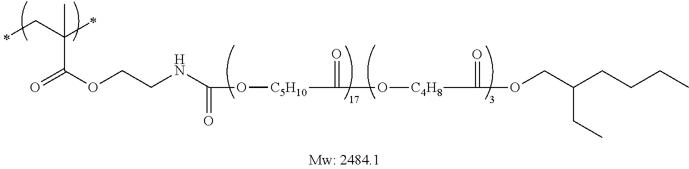 |
| P-8 | 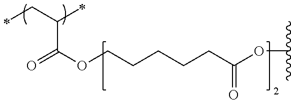 | 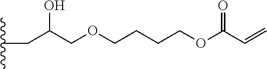 [SMILES: *CC(O)COCCCCOC(=O)C=C] | 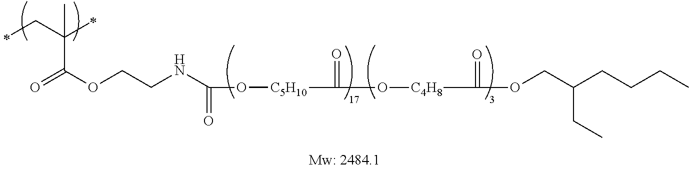 |
| P-9 | 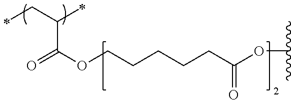 | 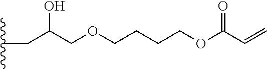 [SMILES: *CC(O)COCCCCOC(=O)C=C] | 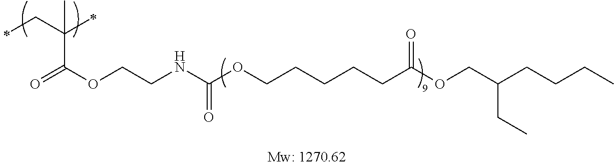 |
| P-10 | 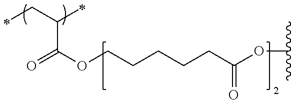 | 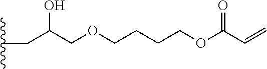 [SMILES: *CC(O)COCCCCOC(=O)C=C] | 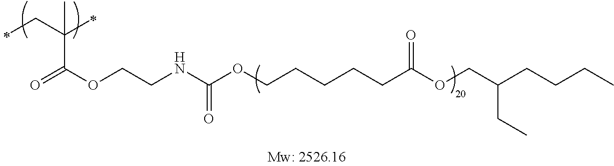 |
| P-11 | 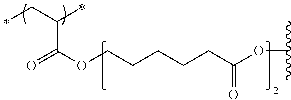 | 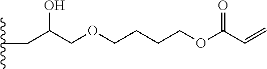 [SMILES: *CC(O)COCCCCOC(=O)C=C] | 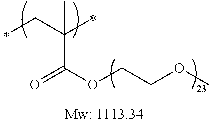 |
| P-12 | 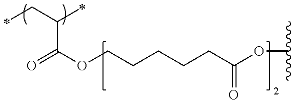 | 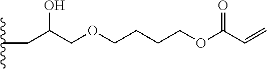 [SMILES: *CC(O)COCCCCOC(=O)C=C] | 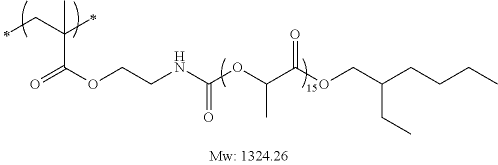 |

| | | Characteristics of compound A | | | Molar ratio [% by mole] | | |
|---|---|---|---|---|---|---|---|
| | Structure of compound A | | Acid value | C═C value | of compound A | | |
| | A-1-3 | Mw | [mgKOH/g] | [mmol/g] | A-1-1 | A-1-2 | A-1-3 |
| P-6 | 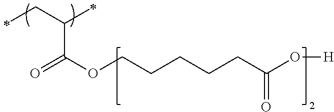 | 22,000 | 78 | 0.7 | 32% | 5% | 63% |
| P-7 | 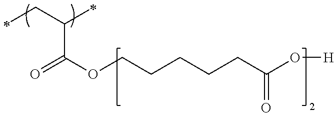 | 18,000 | 78 | 0.7 | 32% | 4% | 64% |
| P-8 | 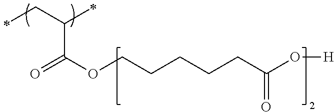 | 20,000 | 78 | 0.47 | 25% | 9% | 67% |
| P-9 | 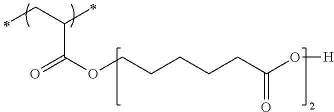 | 19,000 | 78 | 0.7 | 32% | 10% | 58% |
| P-10 | 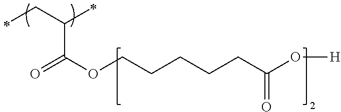 | 21,000 | 78 | 0.7 | 34% | 5% | 61% |
| P-11 | 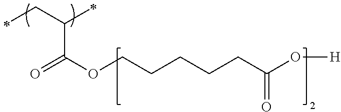 | 18,000 | 78 | 0.7 | 32% | 11% | 57% |
| P-12 | 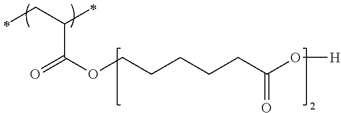 | 17,000 | 78 | 0.7 | 32% | 10% | 58% |

TABLE 2

| | Structure of compound A | | |
|---|---|---|---|
| | A-1-1 | | |
| | | Structure of C═C group | A-1-2 |
| P-13 | 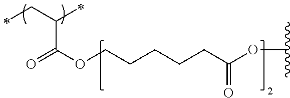 | 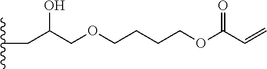 [SMILES: *CC(O)COCCCCOC(=O)C=C] | 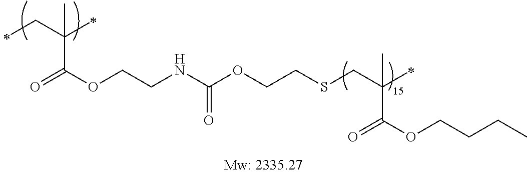 |
| P-14 | 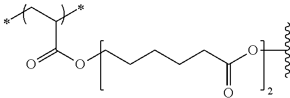 | 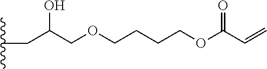 [SMILES: *CC(O)COCCCCOC(=O)C=C] | 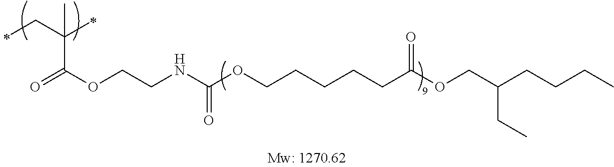 |
| P-15 | 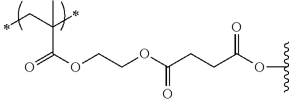 | 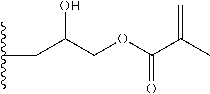 [SMILES: *CC(O)COC(=O)C(=C)C] | 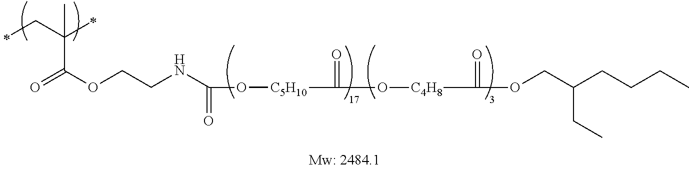 |
| P-16 | 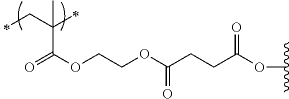 | 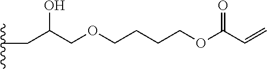 [SMILES: *CC(O)COCCCCOC(=O)C=C] | 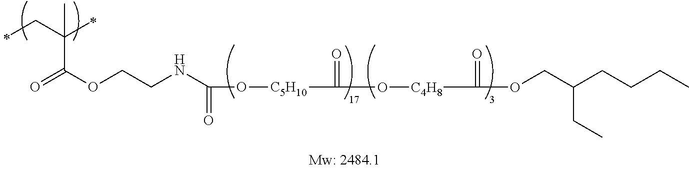 |
| P-17 | 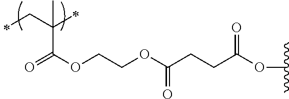 | 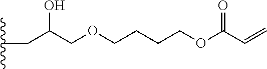 [SMILES: *CC(O)COCCCCOC(=O)C=C] | 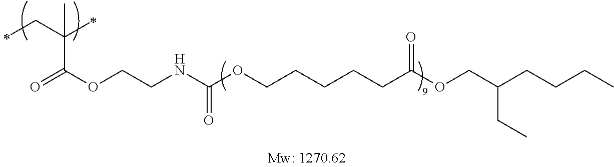 |
| P-18 | 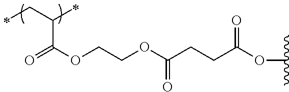 | 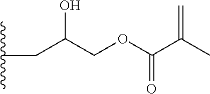 [SMILES: *CC(O)COC(=O)C(=C)C] | 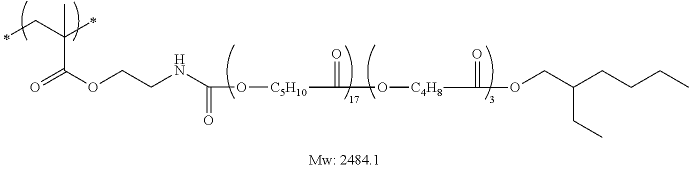 |
| P-19 | 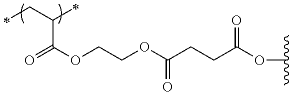 | 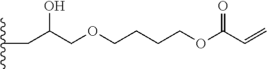 [SMILES: *CC(O)COCCCCOC(=O)C=C] | 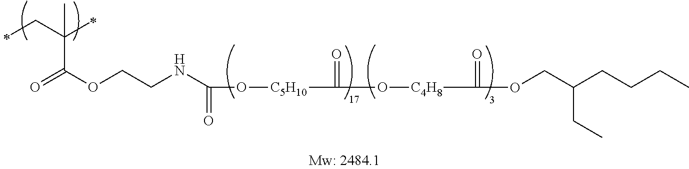 |
| P-20 | 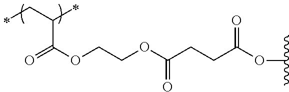 | 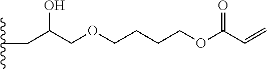 [SMILES: *CC(O)COCCCCOC(=O)C=C] | 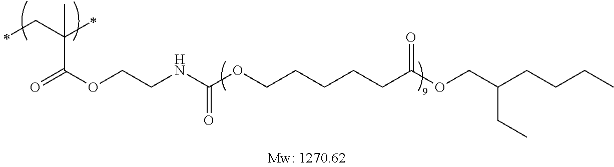 |

| | | Characteristics of compound A | | | Molar ratio [% by mole] | | |
|---|---|---|---|---|---|---|---|
| | Structure of compound A | | Acid value | C═C value | of compound A | | |
| | A-1-3 | Mw | [mgKOH/g] | [mmol/g] | A-1-1 | A-1-2 | A-1-3 |
| P-13 | 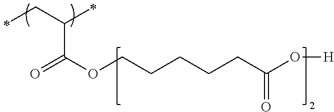 | 23,000 | 78 | 0.7 | 32% | 5% | 64% |
| P-14 | None | 18,000 | 0 | 0.7 | 58% | 42% | 0% |
| P-15 | 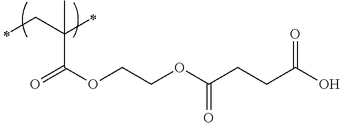 | 21,000 | 78 | 0.7 | 31% | 7% | 62% |
| P-16 | 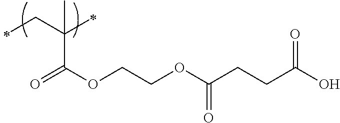 | 22,000 | 78 | 0.7 | 31% | 7% | 62% |
| P-17 | 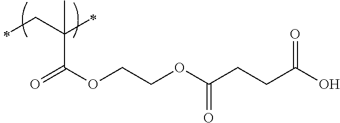 | 19,000 | 78 | 0.7 | 29% | 13% | 58% |
| P-18 | 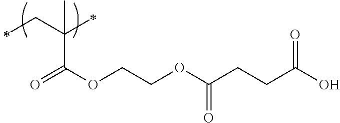 | 20,000 | 78 | 0.7 | 31% | 7% | 62% |
| P-19 | 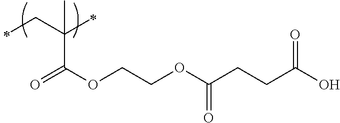 | 21,000 | 78 | 0.7 | 31% | 7% | 62% |
| P-20 | 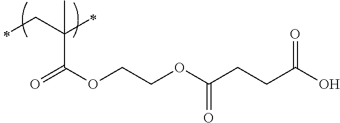 | 20,000 | 78 | 0.7 | 29% | 13% | 58% |

TABLE 3

| | Structure of compound A | | |
|---|---|---|---|
| | A-1-1 | | |
| | | Structure of C═C group | A-1-2 |
| P-21 | 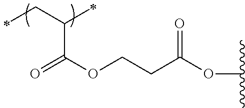 | 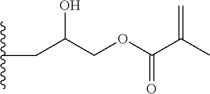 [SMILES: *CC(O)COC(=O)C(=C)C] | 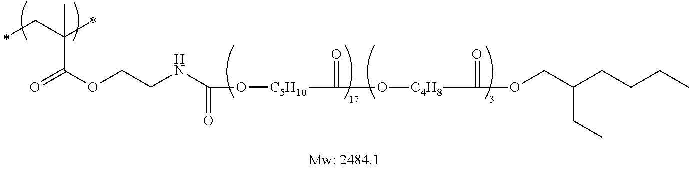 |
| P-22 | 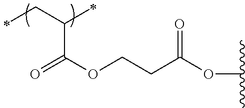 | 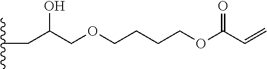 [SMILES: *CC(O)COCCCCOC(=O)C=C] | 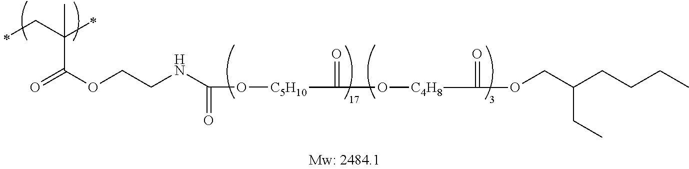 |
| P-23 | 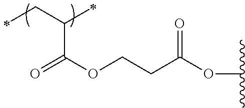 | 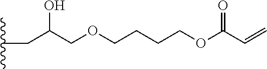 [SMILES: *CC(O)COCCCCOC(=O)C=C] | 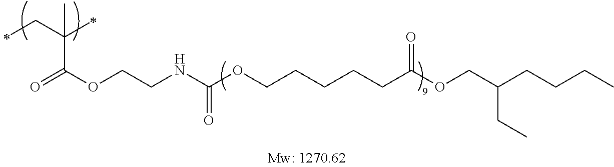 |
| P-24 | 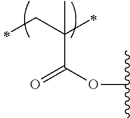 | 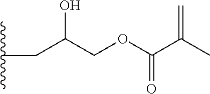 [SMILES: *CC(O)COC(=O)C(=C)C] | 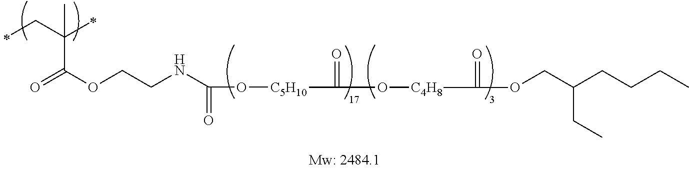 |
| P-25 | 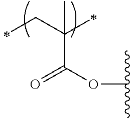 | 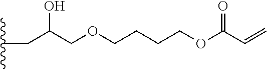 [SMILES: *CC(O)COCCCCOC(=O)C=C] | 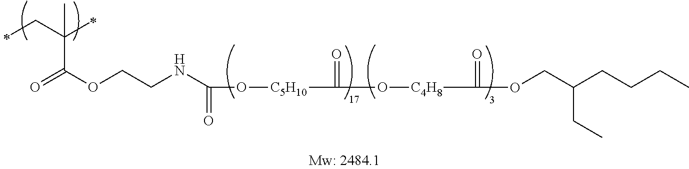 |
| P-26 | 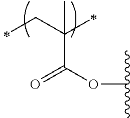 | 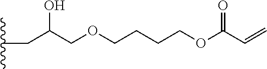 [SMILES: *CC(O)COCCCCOC(=O)C=C] | 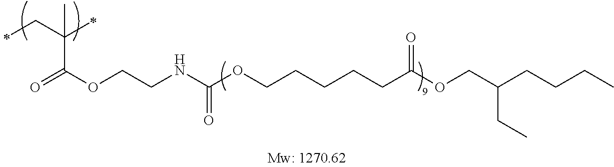 |
| P-27 | 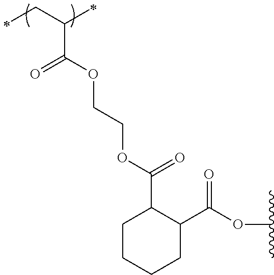 | 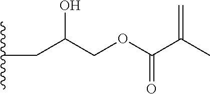 [SMILES: *CC(O)COC(=O)C(=C)C] | 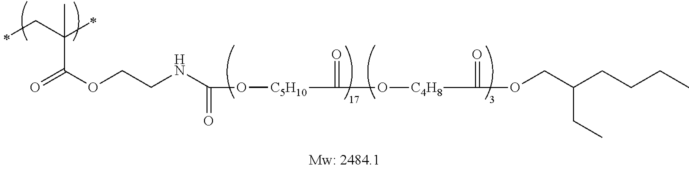 |

| | | Characteristics of compound A | | | Molar ratio [% by mole] | | |
|---|---|---|---|---|---|---|---|
| | Structure of compound A | | Acid value | C═C value | of compound A | | |
| | A-1-3 | Mw | [mgKOH/g] | [mmol/g] | A-1-1 | A-1-2 | A-1-3 |
| P-21 | 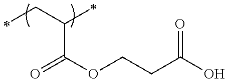 | 22,000 | 78 | 0.7 | 30% | 10% | 60% |
| P-22 | 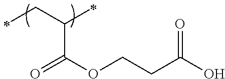 | 20,000 | 78 | 0.7 | 30% | 10% | 60% |
| P-23 | 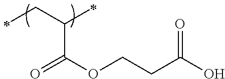 | 21,000 | 78 | 0.7 | 28% | 17% | 55% |
| P-24 | 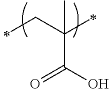 | 18,000 | 78 | 0.7 | 31% | 13% | 56% |
| P-25 | 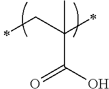 | 21,000 | 78 | 0.7 | 31% | 13% | 56% |
| P-26 | 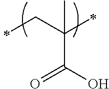 | 22,000 | 78 | 0.7 | 28% | 22% | 50% |
| P-27 | 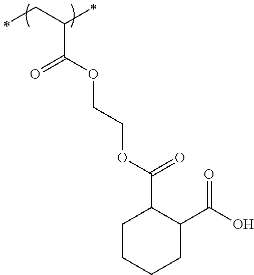 | 20,000 | 78 | 0.7 | 32% | 6% | 62% |

TABLE 4

| | Structure of compound A | | |
|---|---|---|---|
| | A-1-1 | | |
| | | Structure of C═C group | A-1-2 |
| P-28 | 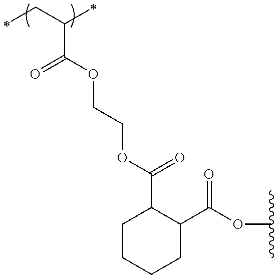 | 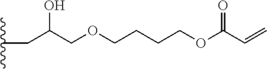 [SMILES: *CC(O)COCCCCOC(=O)C=C] | 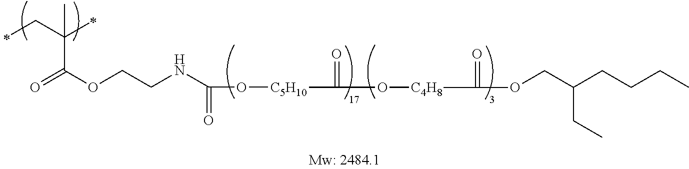 |
| P-29 | 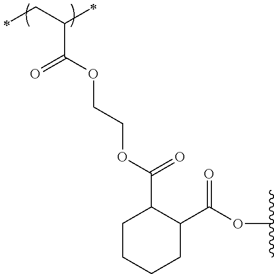 | 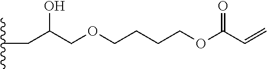 [SMILES: *CC(O)COCCCCOC(=O)C=C] | 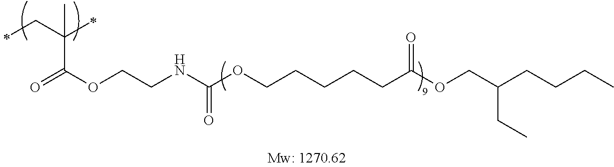 |
| P-30 | 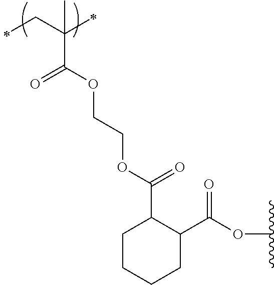 | 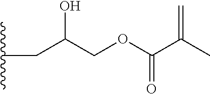 [SMILES: *CC(O)COC(=O)C(=C)C] | 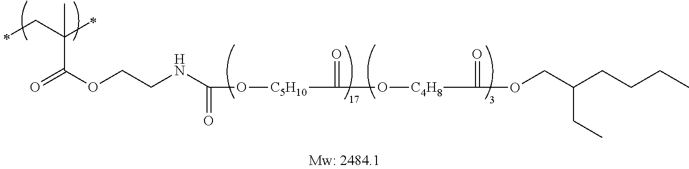 |
| P-31 | 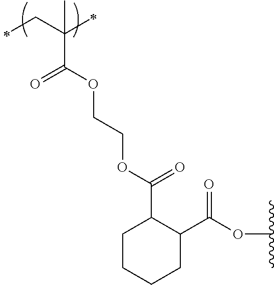 | 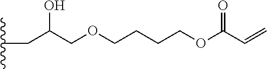 [SMILES: *CC(O)COCCCCOC(=O)C=C] | 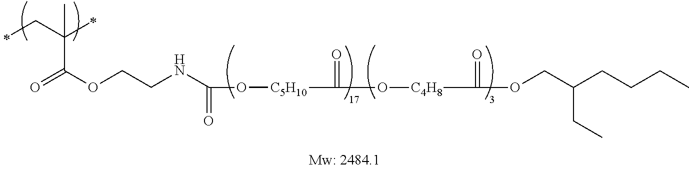 |

| | | Characteristics of compound A | | | Molar ratio [% by mole] | | |
|---|---|---|---|---|---|---|---|
| | Structure of compound A | | Acid value | C═C value | of compound A | | |
| | A-1-3 | Mw | [mgKOH/g] | [mmol/g] | A-1-1 | A-1-2 | A-1-3 |
| P-28 | 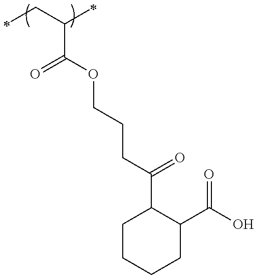 | 21,000 | 78 | 0.7 | 32% | 5% | 63% |
| P-29 | 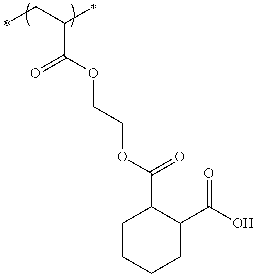 | 20,000 | 78 | 0.7 | 30% | 10% | 60% |
| P-30 | 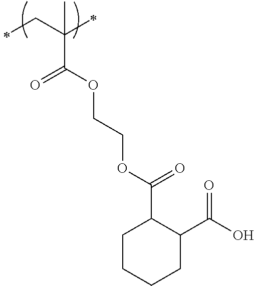 | 23,000 | 78 | 0.7 | 32% | 6% | 62% |
| P-31 | 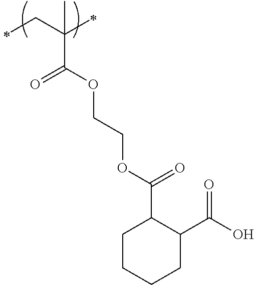 | 22,000 | 78 | 0.7 | 32% | 6% | 62% |

TABLE 5

| | Structure of compound A | | |
|---|---|---|---|
| | A-1-1 | | |
| | | Structure of C═C group | A-1-2 |
| P-32 | 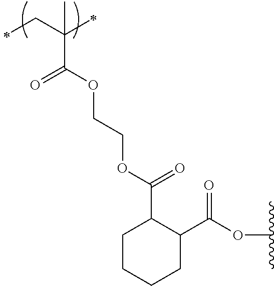 | 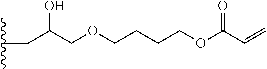 [SMILES: *CC(O)COCCCCOC(=O)C=C] | 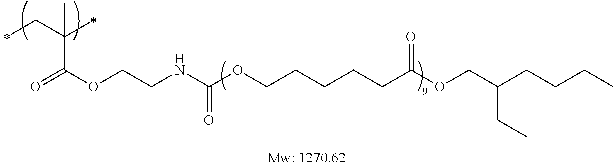 |
| P-33 | 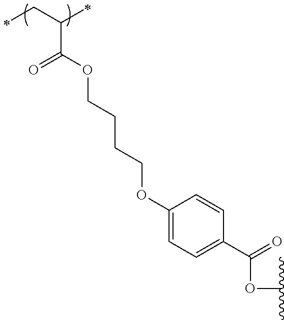 | 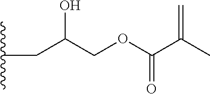 [SMILES: *CC(O)COC(=O)C(=C)C] | 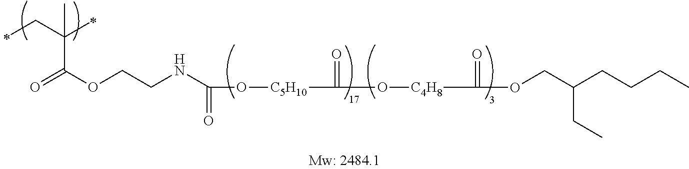 |
| P-34 | 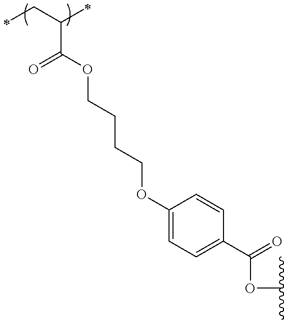 | 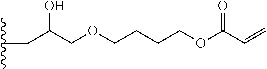 [SMILES: *CC(O)COCCCCOC(=O)C=C] | 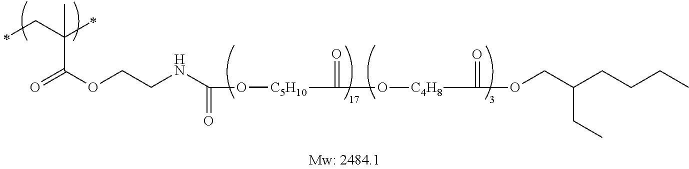 |
| P-35 | 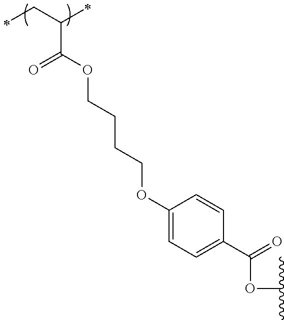 | 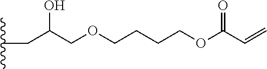 [SMILES: *CC(O)COCCCCOC(=O)C=C] | 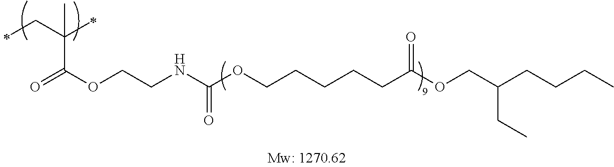 |

| | | Characteristics of compound A | | | Molar ratio [% by mole] | | |
|---|---|---|---|---|---|---|---|
| | Structure of compound A | | Acid value | C═C value | of compound A | | |
| | A-1-3 | Mw | [mgKOH/g] | [mmol/g] | A-1-1 | A-1-2 | A-1-3 |
| P-32 | 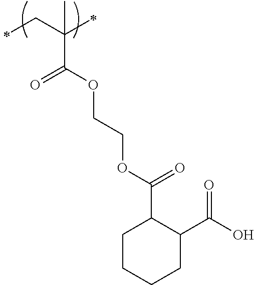 | 19,000 | 78 | 0.7 | 31% | 9% | 60% |
| P-33 | 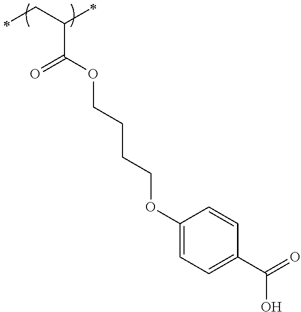 | 21,000 | 78 | 0.7 | 31% | 6% | 62% |
| P-34 | 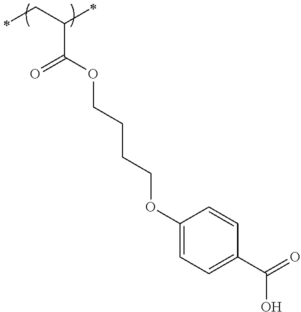 | 22,000 | 78 | 0.7 | 32% | 6% | 63% |
| P-35 | 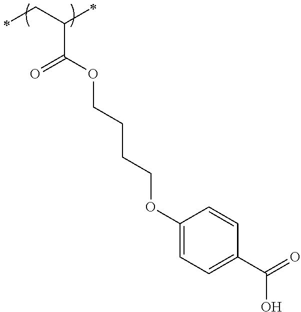 | 20,000 | 78 | 0.7 | 30% | 10% | 60% |

TABLE 6

| | Structure of compound A | | |
|---|---|---|---|
| | A-1-1 | | |
| | | Structure of C═C group | A-1-2 |
| P-36 | 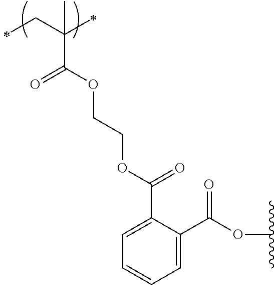 | 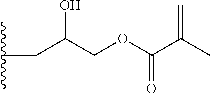 [SMILES: *CC(O)COC(=O)C(=C)C] | 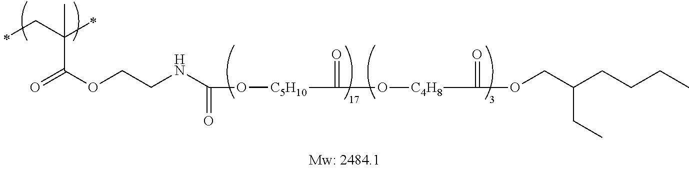 |
| P-37 | 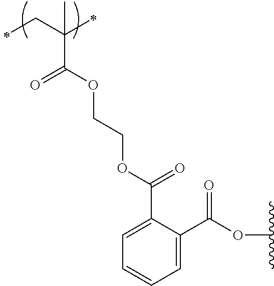 | 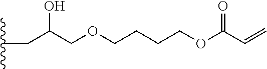 [SMILES: *CC(O)COCCCCOC(=O)C=C] | 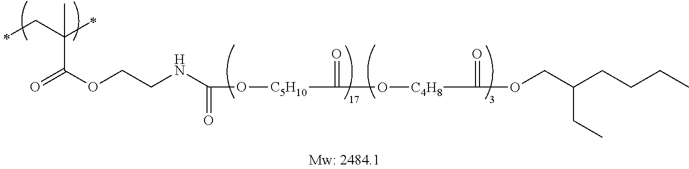 |
| P-38 | 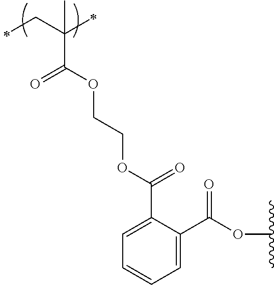 | 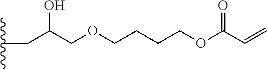 [SMILES: *CC(O)COCCCCOC(=O)C=C] | 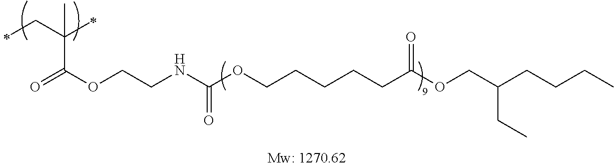 |
| P-39 | 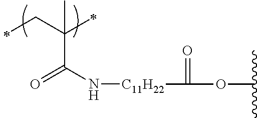 | 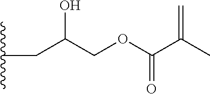 [SMILES: *CC(O)COC(=O)C(=C)C] | 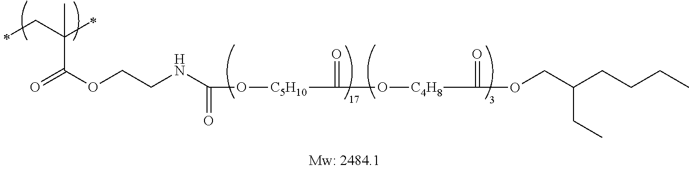 |
| P-40 | 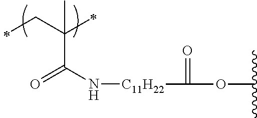 | 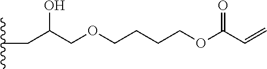 [SMILES: *CC(O)COCCCCOC(=O)C=C] | 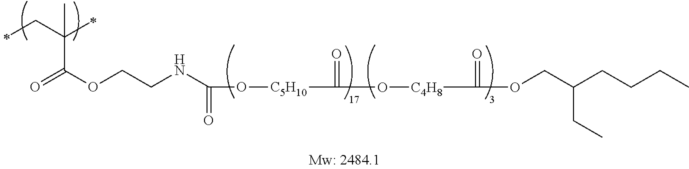 |
| P-41 | 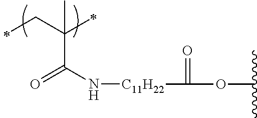 | 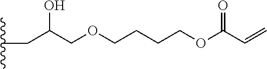 [SMILES: *CC(O)COCCCCOC(=O)C=C] | 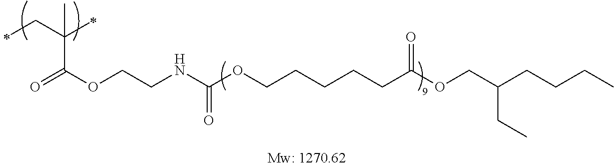 |

| | | Characteristics of compound A | | | Molar ratio [% by mole] | | |
|---|---|---|---|---|---|---|---|
| | Structure of compound A | | Acid value | C═C value | of compound A | | |
| | A-1-3 | Mw | [mgKOH/g] | [mmol/g] | A-1-1 | A-1-2 | A-1-3 |
| P-36 | 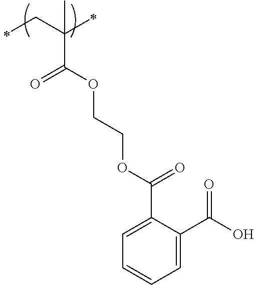 | 21,000 | 78 | 0.7 | 32% | 6% | 62% |
| P-37 | 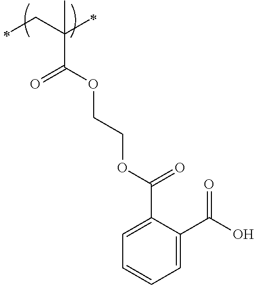 | 20,000 | 78 | 0.7 | 32% | 5% | 63% |
| P-38 | 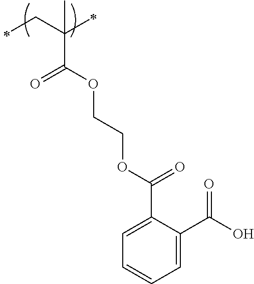 | 19,000 | 78 | 0.7 | 30% | 10% | 60% |
| P-39 | 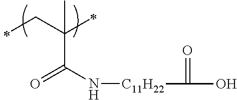 | 20,000 | 78 | 0.7 | 32% | 6% | 63% |
| P-40 | 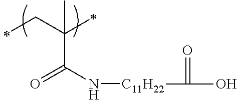 | 21,000 | 78 | 0.7 | 32% | 5% | 63% |
| P-41 | 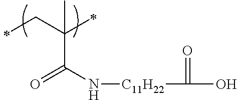 | 18,000 | 78 | 0.7 | 30% | 9% | 60% |

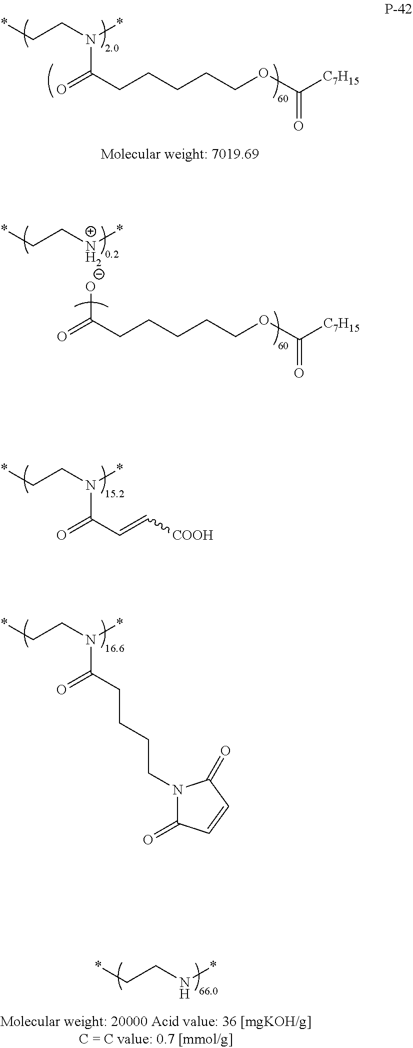

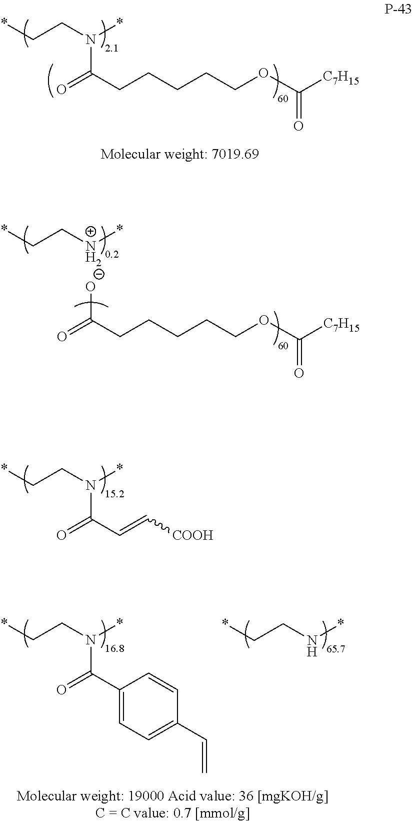

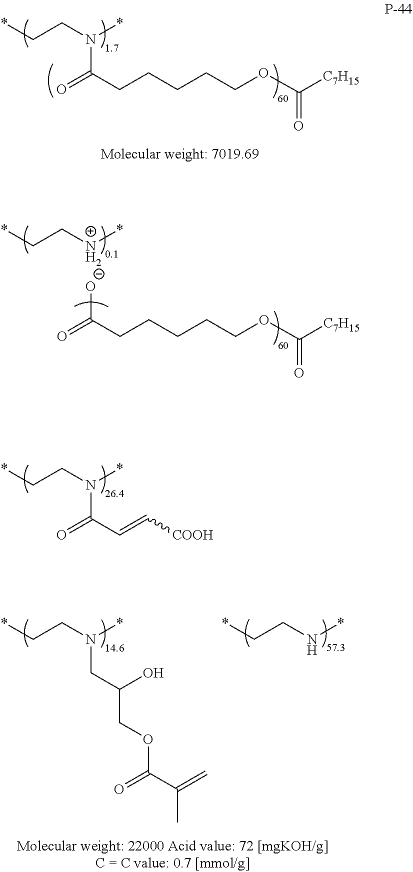

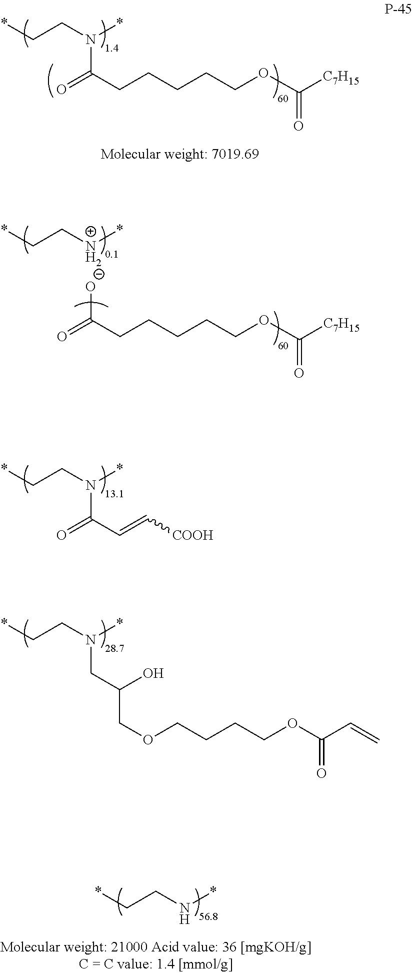

TABLE 7

| | Structure of compound A | | |
|---|---|---|---|
| | A-1-1 | | |
| | | Structure of C═C group | A-1-2 |
| P-46 | 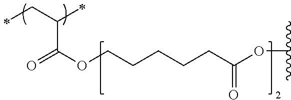 | 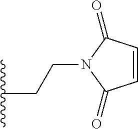 [SMILES: *CCN1C(=O)C=CC1=O] | 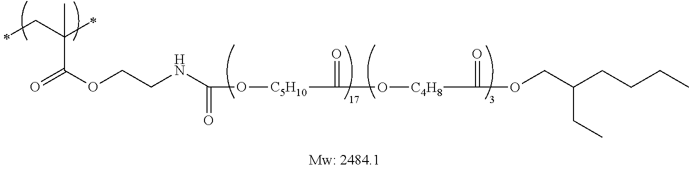 |
| P-47 | 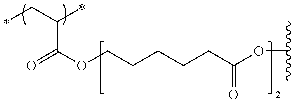 | 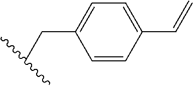 [SMILES: *Cc1ccc(C=C)cc1] | 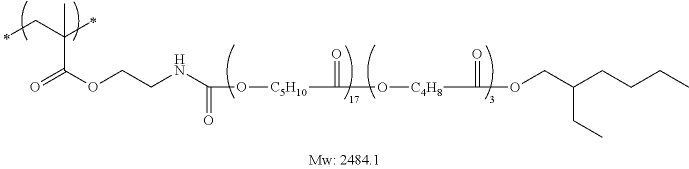 |
| P-48 | 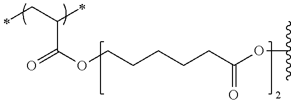 | 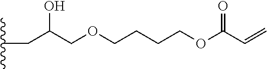 [SMILES: *CC(O)COCCCCOC(=O)C=C] | 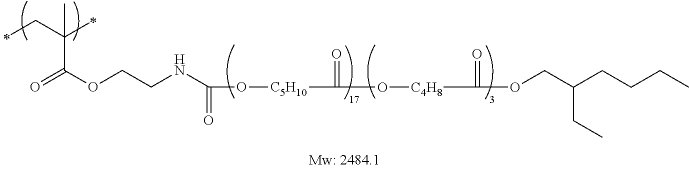 |
| P-49 | 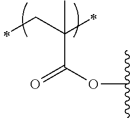 | 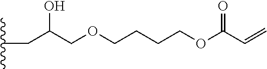 [SMILES: *CC(O)COCCCCOC(=O)C=C] | 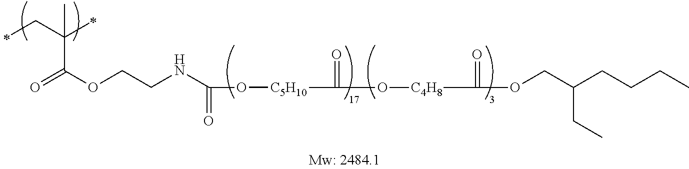 |
| P-50 | 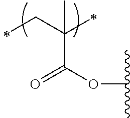 | 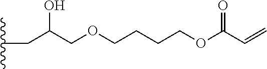 [SMILES: *CC(O)COCCCCOC(=O)C=C] | 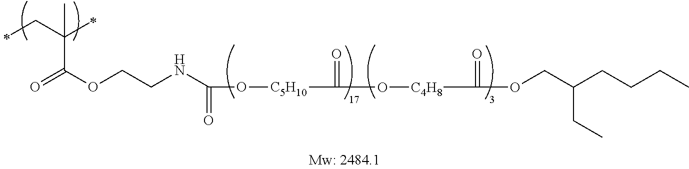 |
| P-51 | 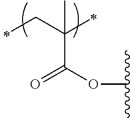 | 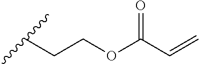 [SMILES: *CCOC(=O)C=C] | 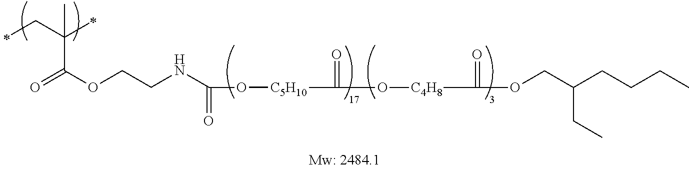 |
| P-52 | 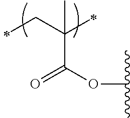 | 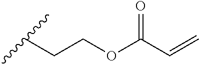 [SMILES: *CCOC(=O)C=C] | 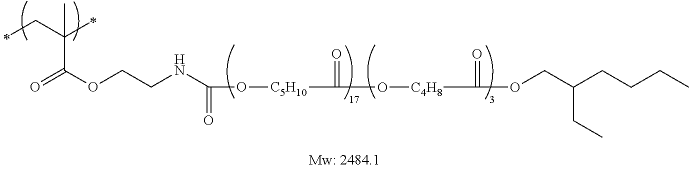 |
| P-53 | 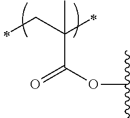 | 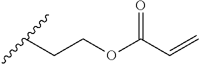 [SMILES: *CCOC(=O)C=C] | 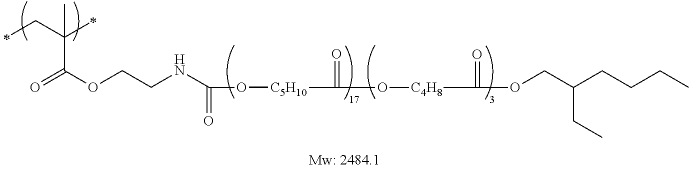 |

| | | Characteristics of compound A | | | Molar ratio [% by mole] | | |
|---|---|---|---|---|---|---|---|
| | Structure of compound A | | Acid value | C═C value | of compound A | | |
| | A-1-3 | Mw | [mgKOH/g] | [mmol/g] | A-1-1 | A-1-2 | A-1-3 |
| P-46 | 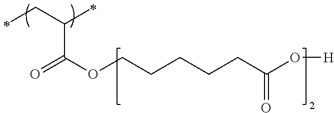 | 21,000 | 78 | 0.7 | 32% | 5% | 63% |
| P-47 | 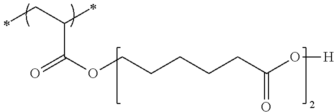 | 18,000 | 78 | 0.7 | 32% | 5% | 63% |
| P-48 | 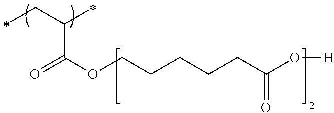 | 22,000 | 24 | 0.7 | 52% | 16% | 32% |
| P-49 | 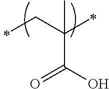 | 21,000 | 104 | 0.47 | 25% | 9% | 66% |
| P-50 | 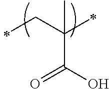 | 20,000 | 156 | 0.7 | 19% | 6% | 75% |
| P-51 | 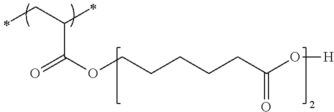 | 22,000 | 78 | 1.4 | 48% | 5% | 47% |
| P-52 | 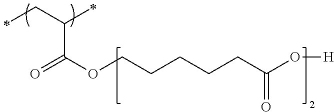 | 18,000 | 78 | 2.1 | 58% | 2% | 39% |
| P-53 | 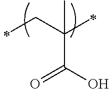 | 18,000 | 78 | 3.0 | 67% | 3% | 31% |

Furthermore, among the compounds A, specific examples of the compound not including a repeating unit having a graft chain include polymers having the following structures.

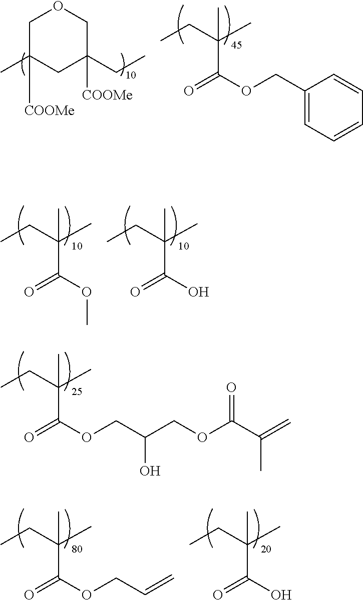

In the present invention, a compound with a molecular weight of less than 3,000 having an ethylenically unsaturated group (hereinafter also referred to as an ethylenically unsaturated group-containing monomer) can also be used as the compound having an ethylenically unsaturated group.

The ethylenically unsaturated group-containing monomer is preferably a compound that is polymerizable by the action of a radical. That is, the ethylenically unsaturated group-containing monomer is preferably a radically polymerizable monomer. The ethylenically unsaturated group-containing monomer is preferably a compound having two or more ethylenically unsaturated groups, and more preferably a compound having three or more ethylenically unsaturated groups. The upper limit of the number of the ethylenically unsaturated groups in the ethylenically unsaturated group-containing monomer is, for example, preferably 15 or less, and more preferably 6 or less. As the ethylenically unsaturated group in the ethylenically unsaturated group-containing monomer, a vinyl group, a styryl group, an allyl group, a methallyl group, or a (meth)acryloyl group is preferable, and the (meth)acryloyl group is more preferable. The ethylenically unsaturated group-containing monomer is preferably a trifunctional to pentadecafunctional (meth)acrylate compound, and more preferably a trifunctional to hexafunctional (meth)acrylate compound.

With regard to examples of the ethylenically unsaturated group-containing monomer, reference can be made to the description in paragraph Nos. 0033 and 0034 of JP2013-253224A, the contents of which are incorporated herein by reference. Examples of the ethylenically unsaturated group-containing monomer include ethyleneoxy-modified pentaerythritol tetraacrylate (as a commercially available product, NK ESTER ATM-35E manufactured by Shin-Nakamura Chemical Co., Ltd.); dipentaerythritol triacrylate (as a commercially available product, KAYARAD D-330 manufactured by Nippon Kayaku Co., Ltd.); dipentaerythritol tetraacrylate (as a commercially available product, KAYARAD D-320 manufactured by Nippon Kayaku Co., Ltd.); dipentaerythritol penta(meth)acrylate (as a commercially available product, KAYARAD D-310 manufactured by Nippon Kayaku Co., Ltd.); dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.); and a compound having a structure in which the (meth)acryloyl group is bonded through an ethylene glycol and/or a propylene glycol residue. In addition, oligomers of the above-described examples can also be used. Further, with regard to this, the description in paragraph Nos. 0034 to 0038 of JP2013-253224A, the contents of which are incorporated herein by reference. Examples of the compound include the polymerizable monomers described in paragraph No. 0477 of JP2012-208494A (corresponding to paragraph No. 0585 of US2012′0235099A), the contents of which are incorporated herein by reference. In addition, diglycerin ethylene oxide (EO)-modified (meth)acrylate (as a commercially available product, M-460 manufactured by Toagosei Co., Ltd.); pentaervthritol tetraacrylate (A-TMMT manufactured by Shin-Nakamura Chemical Co., Ltd.), or 1,6-hexanediol diacrylate (KAYARAD HDDA manufactured by Nippon Kayaku Co., Ltd.) is also preferable. Oligomers of the above-described examples can also be used. Examples thereof include RP-1040 (manufactured by Nippon Kayaku Co., Ltd.). In addition, ARONIX TO-2349 (manufactured by Toagosei Co., Ltd.) can also be used.

The ethylenically unsaturated group-containing monomer may have an acid group such as a carboxyl group, a sulfo group, and a phosphate group. Examples of a commercially available product of the ethylenically unsaturated group-containing monomer having an acid group include ARONIX M-305, M-510, and M-520 (all manufactured by Toagosei Co., Ltd.). The acid value of the ethylenically unsaturated group-containing monomer having an acid group is preferably 0.1 to 40 mgKOH/g. The lower limit is preferably 5 mgKOH/g or more. The upper limit is preferably 30 mgKOH/g or less.

It is also preferable that the ethylenically unsaturated group-containing monomer is a compound having a caprolactone structure. The ethylenically unsaturated group-containing monomer having a caprolactone structure is not particularly limited as long as it has a caprolactone structure in the molecule thereof, and examples thereof include ε-caprolactone-modified polyfunctional (meth)acrylate obtained by esterification of a polyhydric alcohol, (meth)acrylic acid, and ε-caprolactone, the polyhydric alcohol being, for example, trimethylolethane, ditrimethylolethane, trimethylolpropane, ditrimethylolpropane, pentaerythritol, dipentaerythritol, tripentaerythritol, glycerin, diglycerol, and trimethylolmelamine. With regard to examples of the ethylenically unsaturated group-containing monomer having a caprolactone structure, reference can be made to the description in paragraph Nos. 0042 to 0045 of JP2013-253224A, the contents of which are incorporated herein by reference. Examples of the ethylenically unsaturated group-containing monomer having a caprolactone structure include DPCA-20, DPCA-30, DPCA-60, DPCA-120, and the like which are commercially available as KAYARADDPCA series manufactured by Nippon Kayaku Co., Ltd.; SR-494 manufactured by Sartomer, which is a tetrafunctional acrylate having four ethyleneoxy chains, and TPA-330 which is a trifunctional acrylate having three isobutyleneoxy chains.

As the ethylenically unsaturated group-containing monomer, the urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B). JP1981-017654B (JP-S56-017654B), JP1987-039417B (JP-S62-039417B), or JP1987-039418B (JP-S62-039418B) can also be used. In addition, addition-polymerizable compounds having an amino structure or a sulfide structure in the molecules thereof described in JP1988-277653A (JP-S63-277653A), JP1988-260909A (JP-S63-260909A), or JP1989-105238A (JP-H1-105238A). Examples of a commercially available product thereof include URETHANE OLIGOMER UAS-10 and UAB-140 (manufactured by Sanyo-Kokusaku Pulp Co., Ltd.), UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600 and AI-600 (manufactured by Kyoeisha Chemical Co., Ltd.).

The content of the compound having an ethylenically unsaturated group in the photosensitive composition of the embodiment of the present invention is preferably 10% to 50% by mass with respect to the total solid content of the photosensitive composition. The lower limit is preferably 12% by mass or more, and more preferably 14% by mass or more. The upper limit is preferably 45% by mass or less, and more preferably 40% by mass or less. In a case where the content of the compound having an ethylenically unsaturated group is within the range, it is easy to obtain a cured film having suppressed color unevenness.

Furthermore, the content of the compound A (compound with a weight-average molecular weight of 3,000 or more having an ethylenically unsaturated group) in the photosensitive composition of the embodiment of the present invention is preferably 10% to 45% by mass with respect to the total solid content of the photosensitive composition. The lower limit is preferably 12% by mass or more, and more preferably 14% by mass or more. The upper limit is preferably 40% by mass or less, and more preferably 35% by mass or less. In a case where the content of the compound A is within the range, it is easy to produce a cured film having suppressed color unevenness. Further, it is preferable that the compound A includes a compound with a weight-average molecular weight of 3.000 or more, including a repeating unit having an ethylenically unsaturated group and a repeating unit having a graft chain (hereinafter also referred to as a compound a), it is more preferable that the above-mentioned compound a is included in the amount of 60% by mass or more in the total mass of the compound A, and it is still more preferable that the above-mentioned compound a is included in the amount of 70% by mass or more in the total mass of the compound A. According to this aspect, the dispersibility of the color material in the photosensitive composition is good, and thus, it is easy to produce a cured film having further suppressed color unevenness.

Moreover, the content of the above-mentioned compound a in the photosensitive composition of the embodiment of the present invention is preferably 10% to 40% by mass with respect to the total solid content of the photosensitive composition. The lower limit is preferably 12% by mass or more, and more preferably 14% by mass or more. The upper limit is preferably 35% by mass or less, and more preferably 30% by mass or less. In a case where the content of the compound is within the range, the dispersibility of the color material in the photosensitive composition is particularly good, and a cured film having further suppressed color unevenness is easily produced.

The photosensitive composition of the embodiment of the present invention preferably contains the compound having an ethylenically unsaturated group in the amount of 20 to 80 parts by mass with respect to 100 parts by mass. The lower limit is preferably 22 parts by mass or more, and more preferably 24 parts by mass or more. The upper limit is preferably 70 parts by mass or less, and more preferably 60 parts by mass or less.

Incidentally, the photosensitive composition of the embodiment of the present invention preferably contains the compound a in the amount of 20 to 60 parts by mass with respect to 100 parts by mass. The lower limit is preferably 22 parts by mass or more, and more preferably 24 parts by mass or more. The upper limit is preferably 55 parts by mass or less, and more preferably 50 parts by mass or less.

In addition, the photosensitive composition of the embodiment of the present invention preferably contains the compound A in the amount of 20 to 55 parts by mass with respect to 100 parts by mass. The lower limit is preferably 22 parts by mass or more, and more preferably 24 parts by mass or more. The upper limit is preferably 50 parts by mass or less, and more preferably 45 parts by mass or less.

<<Another Resin>>

The photosensitive composition of the embodiment of the present invention can further contain a resin not including an ethylenically unsaturated group (hereinafter also referred to as another resin). Such another resin is blended in, for example, an application for dispersing a pigment in the composition or an application as a binder. Incidentally, a resin which is used for dispersing a pigment in a composition is also referred to as a dispersant. However, such uses of the resin are only exemplary, and the resin can also be used for other purposes, in addition to such uses.

The weight-average molecular weight (Mw) of such another resin is preferably 2,000 to 2,000,000. The upper limit is preferably 1,000,000 or less, and more preferably 500,000 or less. The lower limit is preferably 3,000 or more, and more preferably 5,000) or more.

Examples of such another resin include a (meth)acrylic resin, an epoxy resin, an ene-thiol resin, a polycarbonate resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. These resins may be used singly or as a mixture of two or more kinds thereof.

Such another resin may have an acid group. Examples of the acid group include a carboxyl group, a phosphoric acid group, a sulfo group, and a phenolic hydroxyl group. These acid groups may be of one kind or of two or more kinds thereof. The resin having an acid group may also be used as an alkali-soluble resin.

As the resin having an acid group, a polymer having a carboxyl group in a side chain is preferable. Specific examples thereof include a methacrylic acid copolymer, an acrylic acid copolymer, an itaconic acid copolymer, an crotonic acid copolymer, a maleic acid copolymer, a partially esterified maleic acid copolymer, alkali-soluble phenol resins such as a novolac resin, an acidic cellulose derivative having a carboxyl group in a side chain, and a resin obtained by adding an acid anhydride to a polymer having a hydroxyl group. In particular, a copolymer of a (meth)acrylic acid and another monomer copolymerizable with the (meth)acrylic acid is suitable as the alkali-soluble resin. Examples of another monomer copolymerizable with a (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, and glycidyl (meth)acrylate. Examples of the vinyl compound include styrene, α-methylstyrene, vinyltoluene, acrylonitrile, vinyl acetate. N-vinylpyrrolidone, a polystyrene macromonomer, and a polymethyl methacrylate macromonomer. Further, examples of other monomer include the N-position-substituted maleimide monomers described in JP1998-300922A (JP-H10-300922A), such as N-phenylmaleimide and N-cyclohexylmaleimide. Such other monomers copolymerizable with (meth)acrylic acids may be of one kind or of two or more kinds thereof.

As the resin having an acid group, a benzyl (meth)acrylate/(meth)acrylic acid copolymer, a benzyl (meth)acrylate (meth)acrylic acid/2-hydroxyethyl (meth)acrylate copolymer, or a multicomponent copolymer including benzyl (meth)acrylate/(meth)acrylic acid/other monomers can be preferably used. Further, a copolymer obtained by copolymerizing 2-hydroxyethyl (meth)acrylate and other monomers, the 2-hydroxypropyl (meth)acrylate/polystyrene macromonomer/benzyl methacrylate methacrylic acid copolymer described in JP1995-140654A (JP-H07-140654A), a 2-hydroxy-3-phenoxy propylacrylate/poly methyl methacrylate macromonomer/benzyl methacrylate/methacrylic acid copolymer, a 2-hydroxyethyl methacrylate/polystyrene macromonomer/methyl methacrylate methacrylic acid copolymer, a 2-hydroxyethyl methacrylate/polystyrene macromonomer/benzyl methacrylate/methacrylic acid copolymer, and the like can also be preferably used.

The resin having an acid group is also preferably a polymer including a repeating unit derived from a monomer component including an ether dimer described in the compound A as described above.

The resin having an acid group may include a repeating unit derived from a compound represented by Formula (X).

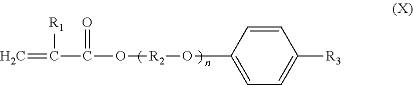

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms, which may include a benzene ring. n represents an integer of 1 to 15.

With regard to the resin having an acid group, reference can be made to the description in paragraph Nos. 0558 to 0571 of JP2012-208494A (paragraph Nos. 0685 to 0700 of the corresponding US2012/0235099A) and paragraph Nos. 0076 to 0099 of JP2012-198408A. Incidentally, a commercially available product can also be used as the resin having an acid group.

The acid value of the resin having an acid group is preferably 30 to 200 mgKOH/g. The lower limit is preferably 50 mgKOH/g or more, and more preferably 70 mgKOH/g or more. The upper limit is preferably 150 mgKOH/g or less, and more preferably 120 mgKOH/g or less.

Examples of the resin having an acid group include a resin having the following structure. In the following structural formulae, Me represents a methyl group.

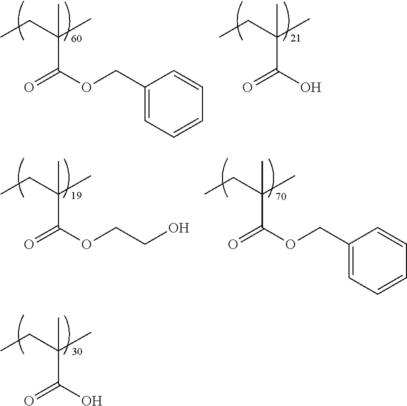

The photosensitive composition of the embodiment of the present invention can also include a resin as the dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70% by mole or more in a case where the total amount of the acid group and the basic group is 100% by mole, and more preferably a resin consisting substantially of only an acid group. The acid group contained in the acidic dispersant (acidic resin) is preferably a carboxyl group. The acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group occupies 50% by mole or more in a case where the total amount of the acid group and the basic group is 100% by mole. The basic group contained in the basic dispersant is preferably an amino group.

The resin used as the dispersant preferably includes a repeating unit having an acid group. By incorporating the repeating unit having an acid group into the resin used as the dispersant, residues generated in the underlying substrate of pixels upon formation of a pattern by photolithography can further be reduced.

It is also preferable that the resin used as the dispersant is a graft copolymer. Since the graft copolymer has affinity with a solvent due to its the graft chain, it is excellent in dispersibility of a pigment and dispersion stability after curing. With regard to details of the graft copolymer, reference can be made to the description in paragraph Nos. 0025 to 0094 of JP2012-255128A, the contents of which are incorporated herein by reference. Further, specific examples of the graft copolymer include the following copolymers. The following resins are also resins having an acid group (alkali-soluble resins). In addition, examples of the graft copolymer include the resins described in paragraph Nos. 0072 to 0094 of JP2012-255128A, the contents of which are incorporated herein by reference.

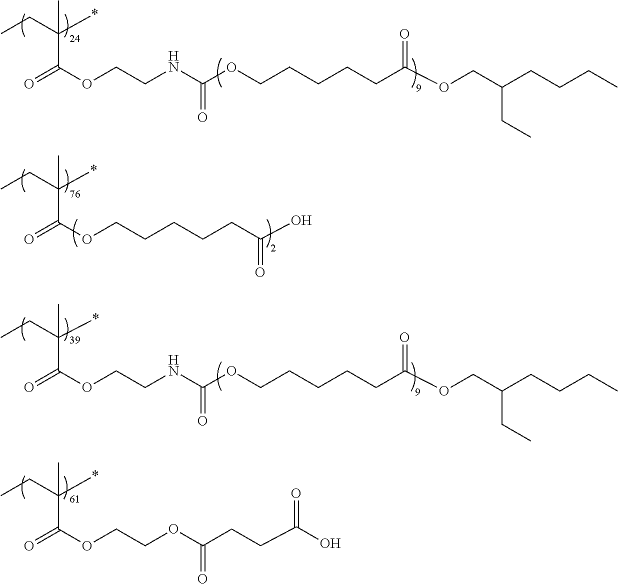

Furthermore, in the present invention, it is also preferable that the resin (dispersant) uses an oligoimine-based dispersant including a nitrogen atom at at least one of a main chain or a side chain. As the oligoimine-based dispersant, a resin having a side chain including a repeating unit having a partial structure X having a functional group with a pKa of 14 or less and a side chain including a side chain Y having 40 to 10,000 atoms, and having a basic nitrogen atom in at least one of the main chain or the side chain is preferable. The basic nitrogen atom is not particularly limited as long as it is a nitrogen atom exhibiting basicity. With regard to the oligoimine-based dispersant, reference can be made to the description in paragraph Nos. 0102 to 0166 of JP2012-255128A, the contents of which are incorporated herein by reference. As specific examples of the oligoimine-based dispersant, the resins described in paragraph Nos. 0168 to 0174 of JP2012-255128A can be used.

The dispersant is commercially available as a commercially available product, and specific examples thereof include Disperbyk-111 (manufactured by BYK Chemie) and SOLSEPERSE 76500 (manufactured by Lubrizol Japan Ltd.). Further, the pigment dispersant described in paragraph Nos. 0041 to 0130 of JP2014-130338A can also be used, the contents of which are incorporated herein by reference. Further, the above-mentioned resin having an acid group or the like can also be used as the dispersant.

In a case where the photosensitive composition of the embodiment of the present invention includes another resin, the content of such another resin is preferably 30% by mass or less, more preferably 20% by mass or less, and still more preferably 10% by mass or less, with respect to the total solid content of the photosensitive composition of the embodiment of the present invention. Further, the photosensitive composition of the embodiment of the present invention may not substantially include such another resin. In a case where the photosensitive composition of the embodiment of the present invention does not substantially include such another resin, the content of such another resin with respect to the total solid content of the photosensitive composition of the embodiment of the present invention is preferably 0.1% by mass or less, more preferably 0.05% by mass or less, and particularly preferably, such another resin is not contained.

<<Photopolymerization Initiator>>

The photosensitive composition of the embodiment of the present invention contains a photopolymerization initiator. The photopolymerization initiator can be appropriately selected from known photopolymerization initiators. For example, a compound having photosensitivity to light in a range from the ultraviolet range to the visible range is preferable. The photopolymerization initiator is preferably photoradical polymerization initiator.

Examples of the photopolymerization initiator include halogenated hydrocarbon derivatives (for example, a compound having a triazine skeleton and a compound having an oxadiazole skeleton), an acylphosphine compound, hexaaryl biimidazole, an oxime compound, an organic peroxide, a thio compound, a ketone compound, an aromatic onium salt, an α-hydroxyketone compound, and an α-aminoketone compound. From the viewpoint of the exposure sensitivity, a trihalomethyl triazine compound, a benzyl dimethyl ketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an aminoacetophenoen compound, a cyclopentadiene-benzene-iron complex, a halomethyl oxadiazole compound, and a 3-aryl-substituted coumarin compound are preferable, a compound selected from an oxime compound, the α-hydroxyketone compound the α-aminoketone compound, and the acylphosphine compound is more preferable, and the oxime compound is still more preferable. With regard to the photopolymerization initiator, reference can be made to the description in paragraphs 0065 to 0111 of JP2014-130173A, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all manufactured by BASF). Examples of a commercially available product of the α-aminoketone compound include IRGACURE-907, IRGACURE-369, IRGACURE-379, and IRGACURE-379EG (all manufactured by BASF). Examples of a commercially available product of the acylphosphine compound include IRGACURE-819 and DAROCUR-TPO (both manufactured by BASF).

As the oxime compound, for example, the compounds described in JP2001-233842A, the compounds described in JP2000-080068A, and the compounds described in JP2006-342166A can be used. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

As the oxime compound, the compounds described in J. C. S. Perkin II (1979). pp. 1653 to 1660, J. C. S. Perkin II (1979), pp. 156 to 162, Journal of Photopolymer Science and Technology (1995), pp. 202 to 232, each of the publications of JP2000-066385A, JP2000-080068A, JP2004-534797A, and JP2006-342166A, or the like can also be used. As a commercially available product of the oxime compound, IRGACURE-OXE01, IRGACURE-OXE02. IRGACURE-OXE03, and IRGACURE-OXE04 (all manufactured by BASF) are also suitably used. In addition, TRONLY TR-PBG-304, TRONLY TR-PBG-309, and TRONLY TR-PBG-305 (manufactured by CHANGZHOU TRONLY NEW ELECTRONIC MATERIALS CO., LTD.), or ADEKA ARKLS NCI-930 and ADEKA OPTOMER N-1919 (all manufactured by ADEKA Corporation, a photopolymerization initiator 2 described in JP2012-014052A) can also be used.

Moreover, as oxime compounds other than the above-described oxime compounds, the compounds described in JP2009-519904A in which oxime is linked to N of a carbazole ring, the compounds described in U.S. Pat. No. 7,626,957B in which a hetero-substituent is introduced into a benzophenone moiety, the compounds described in JP2010-015025A in which a nitro group is introduced into a dye site, the compounds described in US2009-0292039A, the ketoxime compounds described in WO2009/131189A, the compounds described in U.S. Pat. No. 7,556,910B, which contains a triazine skeleton and an oxime skeleton in the same molecule, the compound described in JP2009-221114A, which has a maximum absorption at 405 nm and has good sensitivity to a light source of g-rays, and the like may be used. Preferably, reference can be made to, for example, the descriptions in paragraph Nos. 0274 to 0306 of JP2013-029760A, the contents of which are incorporated herein by reference.

In the present invention, an oxime compound having a fluorene ring can also be used as the photopolymerization initiator. Specific examples of the oxime compound having a fluorene ring include the compounds described in JP2014-137466A, the contents of which are incorporated herein by reference.

In the present invention, an oxime compound having a benzofuran skeleton can also be used as the photopolymerization initiator. Specific examples thereof include the compounds OE-01 to OE-75 described in WO2015/036910A.

In the present invention, an oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compounds (C-3) described in JP2013-164471A. The contents of the publications are incorporated herein by reference.

In the present invention, an oxime compound having a nitro group can also be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

Specific examples of the oxime compound which is preferably used in the present invention are shown below, but the present invention is not limited thereto.

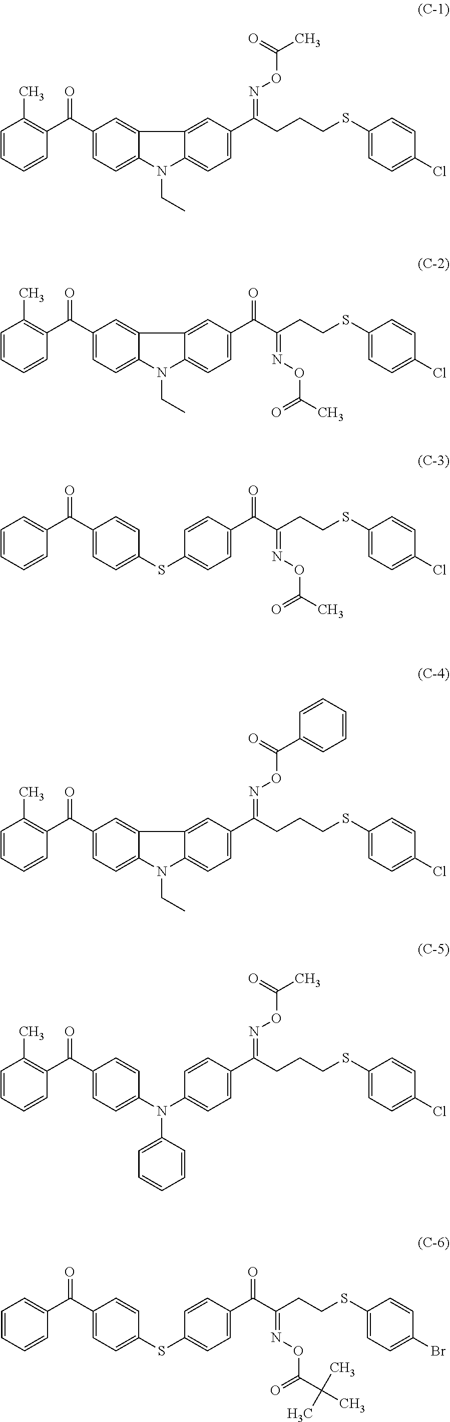 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

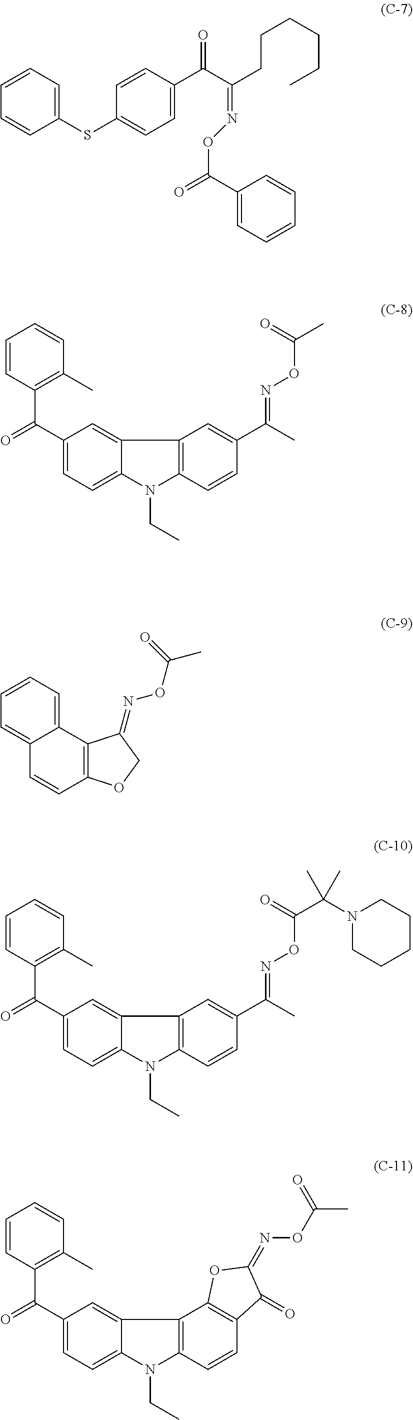 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

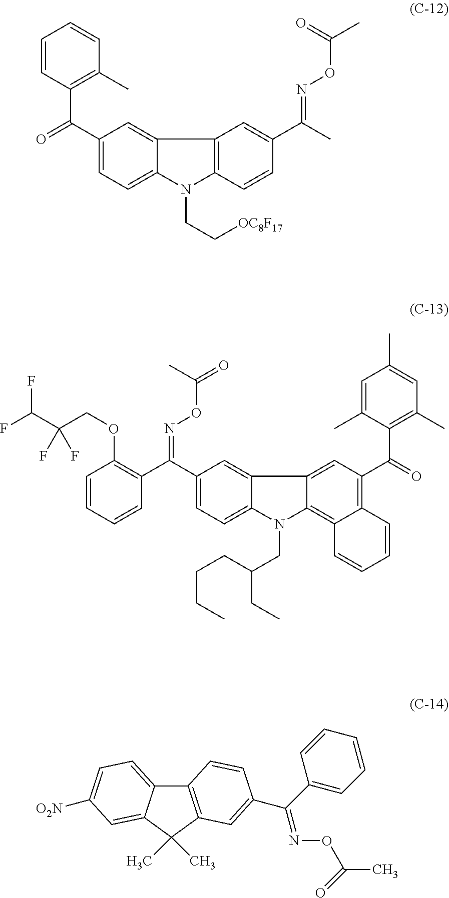

As the oxime compound, the compound having a maximum absorption wavelength in a wavelength range of 350 nm to 500 nm is preferable, the compound having a maximum absorption wavelength in a wavelength range of 360 nm to 480 nm is more preferable. The oxime compound is particularly preferably a compound showing a high absorbance at 365 nm and 405 nm.

From the viewpoint of sensitivity, the molar light absorption coefficient at 365 nm or 405 nm of the oxime compound is preferably 1,000 to 300,000, more preferably 2,000 to 300,000, and particularly preferably 5,000 to 200,000. The molar light absorption coefficient of the compound can be measured using a known method, but specifically, it is preferably measured, for example, by means of an ultraviolet and visible light spectrophotometer (Cary-5 spectrophotometer manufactured by Varian) at a concentration of 0.01 g/L using an ethyl acetate solvent.

The content of the photopolymerization initiator is preferably 0.1% to 50% by mass, more preferably 0.5% to 30% by mass, and still more preferably 1% to 20% by mass, with respect to the total solid content of the photosensitive composition. In a case where the content of the photopolymerization initiator is within the range, good sensitivity and good pattern forming properties are obtained. The photosensitive composition of the embodiment of the present invention may include only one kind or two or more kinds of the photopolymerization initiators. In a case where two or more kinds of the photopolymerization initiators are included, the total amount thereof is preferably within the range.

<<Solvent>>

The photosensitive composition of the embodiment of the present invention preferably contains a solvent. The solvent is preferably an organic solvent. The solvent is not particularly limited as long as it satisfies the solubility of the respective components or the coatability of the photosensitive composition.

Examples of the organic solvent include the following organic solvents. Examples of esters include ethyl acetate, n-butyl acetate, isobutyl acetate, cyclohexyl acetate, amyl formate, isoamyl acetate, butyl propionate, isopropyl butyrate, ethyl butyrate, butyl butyrate, methyl lactate, ethyl lactate, alkyl alkyloxyacetate esters (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), alkyl 3-alkyloxypropionate esters (for example, methyl 3-alkyloxypropionate and ethyl 3-alkyloxypropionate (for example, methyl 3-methoxypropionate, ethyl 3-methoxypropionate, methyl 3-ethoxypropionate, and ethyl 3-ethoxypropionate)), alkyl 2-alkyloxypropionate esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methyl propionate and ethyl 2-alkyloxy-2-methyl propionate (for example, methyl 2-methoxy-2-methyl propionate and ethyl 2-ethoxy-2-methyl propionate), methyl pyruvate, ethyl pyruvate, propyl pyruvate, methyl acetoacetate, ethyl acetoacetate, methyl 2-oxobutanoate, and ethyl 2-oxobutanoate. Examples of ethers include diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate. Examples of the ketones include methyl ethyl ketone, cyclohexanone, cyclopentanone, 2-heptanone, and 3-heptanone. Suitable examples of the aromatic hydrocarbons include toluene and xylene. However, it is preferable in some cases to reduce aromatic hydrocarbons (benzene, toluene, xylene, ethylbenzene, and the like) (for example, the amount can be set to 50 ppm by mass or less, 10 ppm by mass or less, or 1 ppm by mass or less with respect to the total amount of the organic solvent) as a solvent for a reason such as an environmental aspect.

The organic solvents may be used singly or in combination of two or more kinds thereof. In a case where the organic solvents are used in combination of two or more kinds thereof, the solvent is particularly preferably a mixed solution formed of two or more kinds selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol monomethyl ether acetate.

In the present invention, the organic solvent E preferably has a content of peroxides of 0.8 mmol/L or less, and more preferably, it does not substantially include peroxides. Further, it is preferable to use an organic solvent having a small metal content, and for example, the metal content of the organic solvent is preferably 10 ppb by mass or less. The metal content of the organic solvent is at a level of ppt, as desired, and such a high-purity solvent is provided by, for example, Toyo Kasei Kogyo Co., Ltd. (The Chemical Daily, Nov. 13, 2015).

The content of the solvent is preferably an amount such that the total solid content of the photosensitive composition is 5% to 80% by mass. The lower limit is preferably 10% by mass or more. The upper limit is preferably 60% by mass or less, more preferably 50% by mass or less, and still more preferably 40% by mass or less.

<<Compound Having Epoxy Group>>

The photosensitive composition of the present invention can contain a compound having an epoxy group (hereinafter also referred to as an epoxy compound). The epoxy compound is preferably a compound having 1 to 100 epoxy groups per molecule. The lower limit of the number of the epoxy groups is more preferably 2 or more. The upper limit of the number of the epoxy groups can be set to, for example, 10 or less, or to 5 or less.

The epoxy equivalent (=the molecular weight of the epoxy compound/the number of epoxy groups) of the epoxy compound is preferably 500 g/equivalent or less, more preferably 100 to 400 g/equivalent, and still more preferably 100 to 300 g/equivalent.

The epoxy compound may be either a low-molecular-weight compound (for example, a molecular weight of less than 1,000) or a polymer compound (macromolecule) (for example, a molecular weight of 1,000 or more, and in a case of a polymer, a weight-average molecular weight of 1,000 or more). The weight-average molecular weight of the epoxy compound is preferably 200 to 100,000, and more preferably 500 to 50,000. The upper limit of the weight-average molecular weight is more preferably 10,000 or less, still more preferably 5,000 or less, and even still more preferably 3,000 or less.

Examples of a commercially available product of the epoxy compound include EHPE3150 (manufactured by Daicel Chemical Industries, Ltd.). As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A can also be used. The contents of the publications are incorporated herein by reference.

In a case where the photosensitive composition of the embodiment of the present invention contains an epoxy compound, the content of the epoxy compound is preferably 0.1% to 40%0/by mass with respect to the total solid content of the photosensitive composition. The lower limit is, for example, more preferably 0.5% by mass or more, and still more preferably 1% by mass or more. The upper limit is, for example, more preferably 30% by mass or less, and still more preferably 20% by mass or less. These epoxy compounds may be used singly or in combination of two or more kinds thereof. In a case where the epoxy compounds are used in combination of two or more kinds thereof, the total amount thereof is preferably within the range.

<<Curing Accelerator>>

The photosensitive composition of the embodiment of the present invention may include a curing accelerator for the purpose of improving the hardness of a pattern or lowering a curing temperature. Examples of the curing accelerator include a thiol compound. Examples of the thiol compound include a polyfunctional thiol compound having two or more mercapto groups in a molecule thereof. The polyfunctional thiol compound may also be added for the purpose of alleviating problems in stability, smell, developability, adhesiveness, or the like. The polyfunctional thiol compound is preferably a secondary alkanethiol, and more preferably a compound having a structure represented by Formula (T1).

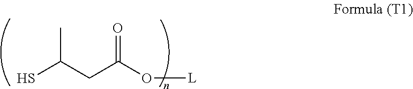

(In Formula (T1), n represents an integer of 2 to 4, and L represents a divalent to tetravalent linking group.)

In Formula (T1), it is preferable that L is an aliphatic group having 2 to 12 carbon atoms. In Formula (T1), it is more preferable that n is 2 and L is an alkylene group having 2 to 12 carbon atoms. Specific examples of the polyfunctional thiol compounds include compounds represented by Structural Formulae (T2) to (T4), and the compound represented by Formula (T2) is preferable. These thiol compounds can be used singly or in combination of two or more kinds thereof.

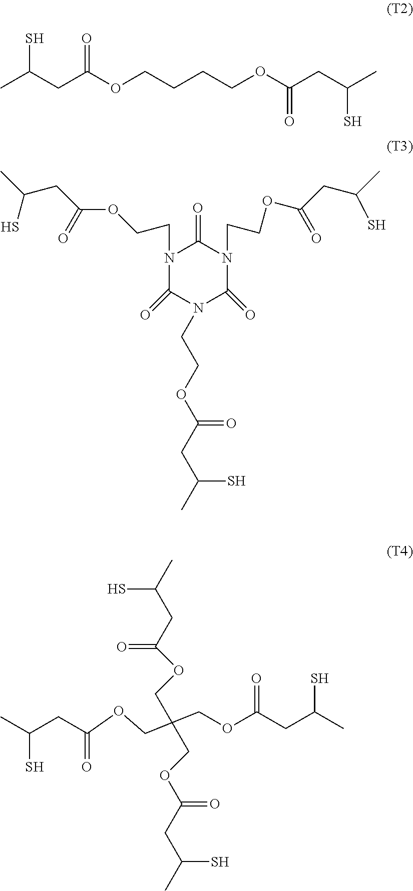

Moreover, as the curing accelerator, a methylol-based compound (for example, the compounds exemplified as a crosslinking agent in paragraph No. 0246 of JP2015-034963A), amines, phosphonium salts, amidine salts, amide compounds (each of which are the curing agents described in, for example, paragraph No. 0186 of JP2013-041165A), base generators (for example, the ionic compounds described in JP2014-055114A), isocyanate compounds (for example, the compounds described in paragraph No. 0071 of JP2012-150180A), alkoxysilane compounds (for example, the alkoxysilane compounds having epoxy groups, described in JP2011-253054A), onium salt compounds (for example, the compounds exemplified as an acid generator in paragraph No. 0216 of JP2015-034963A, and the compounds described in JP2009-180949A), or the like can be used.

In a case where the photosensitive composition of the embodiment of the present invention contains the curing accelerator, the content of the curing accelerator is preferably 0.3% to 8.9% by mass, and more preferably 0.8% to 6.4% by mass, with respect to the total solid content of the photosensitive composition.

<<Pigment Derivative>>

The photosensitive composition of the embodiment of the present invention preferably contains a pigment derivative. Examples of the pigment derivative include a compound having a structure in which a part of a chromophore is substituted with an acid group, a basic group, or a phthalimidemethyl group.

Examples of a chromophore constituting the pigment derivative include a quinoline-based skeleton, a benzimidazolone-based skeleton, a diketopyrrolopyrrole-based skeleton, an azo-based skeleton, a phthalocyanine-based skeleton, an anthraquinone-based skeleton, a quinacridone-based skeleton, a dioxazine-based skeleton, a perinone-based skeleton, a perylene-based skeleton, a thioindigo-based skeleton, an isoindoline-based skeleton, an isoindolinone-based skeleton, a quinophthalone-based skeleton, a threne-based skeleton, and a metal complex-based skeleton, the quinoline-based skeleton, the benzimidazolone-based skeleton, the diketopyrrolopyrrole-based skeleton, the azo-based skeleton, the quinophthalone-based skeleton, the isoindoline-based skeleton, and the phthalocyanine-based skeleton are preferable, and the azo-based skeleton and the benzimidazolone-based skeleton are more preferable. As the acid group contained in the pigment derivative, a sulfo group or a carboxyl group is preferable, and the sulfo group is more preferable. As the basic group contained in the pigment derivative, an amino group is preferable, and a tertiary amino group is more preferable. With regard to specific examples of the pigment derivative, reference can be made to the description in paragraph Nos. 0162 to 0183 of JP2011-252065A, the contents of which are incorporated herein by reference.

In a case where the photosensitive composition of the embodiment of the present invention contains a pigment derivative, the content of the pigment derivative is preferably 1 to 30 parts by mass, and more preferably 3 to 20 parts by mass, with respect to 100 parts by mass of the pigment. The pigment derivative may be used singly or in combination of two or more kinds thereof.

<<Surfactant>>

The photosensitive composition of the embodiment of the present invention preferably contains a surfactant. As the surfactant, various surfactants such as a fluorine-based surfactant, a nonionic surfactant, a cationic surfactant, an anionic surfactant, and a silicone-based surfactant can be used, and the fluorine-based surfactant is preferable for a reason that coatability can be further improved.

By incorporating the fluorine-based surfactant into the photosensitive composition of the embodiment of the present invention, liquid characteristics in a case of preparation of a coating liquid are further improved, and thus, the evenness of coating thickness can be further improved. That is, in a case where a film is formed using to which a photosensitive composition containing the fluorine-based surfactant has been applied, the interface tension between a surface to be coated and the coating liquid is reduced to improve wettability with respect to the surface to be coated, and enhance coatability with respect to the surface to be coated. Therefore, formation of a film with a uniform thickness which exhibits little coating unevenness can be more suitably performed.

The fluorine content in the fluorine-based surfactant is preferably 3% to 40% by mass, more preferably 5% to 30% by mass, and particularly preferably 7% to 25% by mass. The fluorine-based surfactant in which the fluorine content falls within this range is effective in terms of the evenness of the thickness of the coating film or liquid saving properties, and the solubility of the surfactant in the photosensitive composition is also good.

Examples of the fluorine-based surfactant include MEGAFACE F171, F172, F173, F176, F177, F141, F142, F143, F144, R30, F437, F475, F479, F482, F554, and F780 (all manufactured by DIC Corporation), FLUORAD FC430, FC431, and FC171 (all manufactured by Sumitomo 3M), SURFLON S-382, SC-101. SC-103, SC-104, SC-105, SC-1068, SC-381, SC-383, and S-393, and KH-40 (all manufactured by Asahi Glass Co., Ltd.), and PF636, PF656, PF6320, PF6520, and PF7002 (all manufactured by OMNOVA). Further, as the fluorine-based surfactant, the compounds described in paragraph Nos. 0015 to 0158 of JP2015-117327A, and the compounds described in paragraph Nos. 0117 to 0132 of JP2011-132503A can be used. As the fluorine-based surfactant, a block polymer can also be used, and specific examples thereof include the compounds described in JP2011-089090A.

As the fluorine-based surfactant, an acrylic compound in which by application of heat to a molecular structure containing a functional group having a fluorine atom, in which the functional group containing a fluorine atom is cut to volatilize a fluorine atom, can also be suitably used. Examples of the fluorine-based surfactant include MEGAFACE DS series (manufactured by DIC Corporation, The Chemical Daily, Feb. 22, 2016, Nikkei Business Daily, Feb. 23, 2016), for example, MEGAFACE DS-21, which may also be used.

As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used, and the following compounds are also exemplified as a fluorine-based surfactant for use in the present invention. In the following in the formula, % representing the ratio of the repeating unit is % by mole.

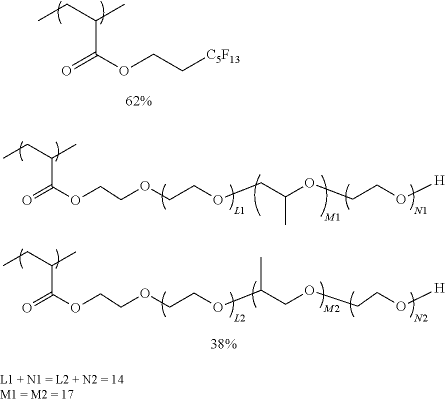

The weight-average molecular weight of the compounds is preferably 3,000 to 50,000, and is, for example, 14,000.

A fluorine-containing polymer having an ethylenically unsaturated bonding group in a side chain can also be used as the fluorine-based surfactant. Specific examples thereof include the compounds described in paragraph Nos. 0050 to 0090 and paragraph Nos. 0289 to 0295 of JP2010-164965A. Examples of commercially available products thereof include MEGAFACE RS-101, RS-102, RS-718-K, and RS-72-K, all of which are manufactured by DIC Corporation.

Examples of the nonionic surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSEPERSE 20000 (manufactured by Lubrizol Japan Ltd.), NCW-101, NCW-1001, and NCW-1002 (manufactured by Wako Pure Chemical Industries, Ltd.), PIONIN D-6112, D-6112-W, and D-6315 (manufactured by Takemoto Oil & Fat Co., Ltd.), and OLFINE E1010, and SURFYNOL 104, 400, and 440 (manufactured by Nissin chemical industry Co., Ltd.).

Specific examples of the cationic surfactant include an organosiloxane polymer KP341 (manufactured by Shin-Etsu Chemical Co., Ltd.), a (meth)acrylic acid-based (co)polymer POLYFLOW No. 75, No. 90, and No. 95 (manufactured by KYOEISHA CHEMICAL CO., LTD.), and WOO 1 (manufactured by Yusho Co., Ltd.).

Examples of the anionic surfactant include W004, W005, and W017 (manufactured by Yusho Co., Ltd.), and BL (manufactured by Sanyo Chemical Industries, Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Toray Co., Ltd.), TSF-4440, TSF-4300, TSF-4445, TSF-4460, and TSF-4452 (all manufactured by Momentive Performance Materials Co., Ltd.), KP341, KF6001, and KF6002 (all manufactured by Shin-Etsu Chemical Co., Ltd.), and BYK307, BYK323, and BYK330 (all manufactured by BYK Chemie).

The content of the surfactant is preferably 0.001% to 2.0% by mass, and more preferably 0.005% to 1.0% by mass, with respect to the total solid content of the photosensitive composition. The surfactant may be used singly or in combination of two or more kinds thereof. In a case where two or more kinds of the surfactants are included, the total amount thereof is preferably within the range.

<<Silane Coupling Agent>>

The photosensitive composition of the embodiment of the present invention can contain a silane coupling agent. In the present invention, the silane coupling agent means a silane compound having a hydrolyzable group and another functional group. Further, the hydrolyzable group refers to a substituent that can be directly linked to a silicon atom to generate a siloxane bond by a hydrolysis reaction and/or a condensation reaction. Examples of the hydrolyzable group include a halogen atom, an alkoxy group, and an acyloxy group.

The silane coupling agent is preferably a silane compound having at least one selected from a vinyl group, an epoxy group, a styryl group, a methacryl group, an amino group, an isocyanurate group, a ureido group, a mercapto group, a sulfide group, or an isocyanate group, or an alkoxy group. Specific examples of the silane coupling agent include N-β-aminoethyl-γ-aminopropyl methyldimethoxysilane (KBM-602, manufactured by Shin-Etsu Chemical Co., Ltd.), N-β-aminoethyl-γ-aminopropyl trimethoxysilane (KBM-603, manufactured by Shin-Etsu Chemical Co., Ltd.), N-3-aminoethyl-γ-aminopropyl triethoxysilane (KBE-602, manufactured by Shin-Etsu Chemical Co., Ltd.), γ-aminopropyl trimethoxysilane (KBM-903, manufactured by Shin-Etsu Chemical Co., Ltd.). γ-aminopropyl triethoxysilane (KBE-903, manufactured by Shin-Etsu Chemical Co., Ltd.), 3-methacryloxypropyl trimethoxysilane (KBM-503, manufactured by Shin-Etsu Chemical Co., Ltd.), and 3-glycidoxypropyl trimethoxysilane (KBM-403, manufactured by Shin-Etsu Chemical Co., Ltd.). With regard to details of the silane coupling agent, reference can be made to the description in paragraph Nos. 0155 to 0158 of JP2013-254047A, the contents of which are incorporated herein by reference.

In a case where the photosensitive composition of the embodiment of the present invention contains a silane coupling agent, the content of the silane coupling agent is preferably 0.001% to 20% by mass, more preferably 0.01% to 10% by mass, and particularly preferably 0.1% to 5% by mass, with respect to the total solid content of the photosensitive composition. The photosensitive composition of the embodiment of the present invention may include one kind or two or more kinds of the silane coupling agents. In a case where the photosensitive composition includes two or more kinds of the silane coupling agent, the total amount thereof is preferably within the range.

<<Polymerization Inhibitor>>

The photosensitive composition of the embodiment of the present invention can contain a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), and an N-nitrosophenylhydroxylamine salt (an ammonium salt, a cerous salt, or the like).

In a case where the photosensitive composition of the embodiment of the present invention contains a polymerization inhibitor, the content of the polymerization inhibitor is preferably 0.01% to 5% by mass with respect to the total solid content of the photosensitive composition. The photosensitive composition of the embodiment of the present invention may include one kind or two or more kinds of the polymerization inhibitor. In a case where the photosensitive composition includes two or more kinds of the polymerization inhibitor, the total amount thereof is preferably within the range.

<<Ultraviolet Absorber>>

The photosensitive composition of the embodiment of the present invention can contain an ultraviolet absorber. As the ultraviolet absorber, a conjugated diene compound, an aminobutadiene compound, a methyldiebenzoyl compound, a coumarin compound, a salicylate compound, a benzophenone compound, a benzotriazole compound, an acrylonitrile compound, a hydroxyphenyltriazine compound, or the like can be used. With regard to details thereof, reference can be made to the description in paragraph Nos. 0052 to 0072 of JP2012-208374A and paragraph Nos. 0317 to 0334 of JP2013-068814A, the contents of which are incorporated herein by reference. Examples of commercially available products of the ultraviolet absorber include UV-503 (manufactured by Daito Chemical Co., Ltd.). In addition, as the benzotriazole compound, MYUA series manufactured by Miyoshi Oil & Fat Co., Ltd. (The Chemical Daily, Feb. 1, 2016) may be used.

In a case where the photosensitive composition of the embodiment of the present invention contains an ultraviolet absorber, the content of the ultraviolet absorber is preferably 0.1% to 10% by mass, more preferably 0.1% to 5% by mass, and particularly preferably 0.1% to 3% by mass, with respect to the total solid content of the photosensitive composition.

Further, only one kind or two or more kinds of the ultraviolet absorbers may be used. In a case where two or more kinds of the ultraviolet absorbers are included, the total amount thereof is preferably within the range.

<<Other Additives>>

Various additives such as a filler, an adhesion promoter, an antioxidant, and an aggregation inhibitor can be blended into the photosensitive composition of the embodiment of the present invention, as desired. Examples of these additives include the additives described in paragraph Nos. 0155 and 0156 of JP2004-295116A, the contents of which are incorporated herein by reference. Further, as the antioxidant, for example, a phenol compound, a phosphorus-based compound (for example, the compounds described in paragraph No. 0042 of JP2011-090147A), a thioether compound, or the like can be used. Examples of a commercially available product thereof include ADEKA STAB series (AO-20, AO-30, AO-40, AO-50, AO-50F, AO-60, AO-60G, AO-80, AO-330, and the like), all of which are manufactured by ADEKA. Only one kind or two or more kinds of the antioxidants may be used as a mixture of two or more kinds thereof. The photosensitive composition of the embodiment of the present invention can contain the sensitizers or the light stabilizers described in paragraph No. 0078 of JP2004-295116A, or the thermal polymerization inhibitors described in paragraph No. 0081 of the same publication.

There are some cases where a metal element is included in the photosensitive composition according to raw materials and the like, but from the viewpoint of suppression of generation of defects, or the like, the content of Group 2 elements (calcium, magnesium, and the like) in the photosensitive composition is preferably 50 ppm by mass or less, and more preferably 0.01 to 10 ppm by mass. Further, the total amount of the inorganic metal salts in the photosensitive composition is preferably 100 ppm by mass or less, and more preferably 0.5 to 50 ppm by mass.

The moisture content in the photosensitive composition of the embodiment of the present invention is usually 3% by mass or less, preferably 0.01% to 1.5% by mass, and more preferably in the range of 0.1% to 1.0% by mass. The moisture content can be measured by a Karl Fischer method.

The photosensitive composition of the embodiment of the present invention can be used after its viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a viscometer RE85L (rotor: 1°34′×R24, measurement range of 0.6 to 1,200 mPa·s) manufactured by Toki Sangyo Co., Ltd.

A storage container for the photosensitive composition of the embodiment of the present invention is not particularly limited, and a known storage container can be used. Further, as the storage container, it is also preferable to use a multilayer bottle having an inner wall constituted with six layers from six kinds of resins or a bottle having a 7-layer structure from 6 kinds of resins for the purpose of suppressing incorporation of impurities into raw materials or compositions. Examples of such a container include the containers described in JP2015-123351A.

The photosensitive composition of the embodiment of the present invention can be preferably used as a photosensitive composition for forming a colored layer in a color filter. Examples of the coloring layer include a red colored layer, a green colored layer, a blue colored layer, a magenta colored layer, a cyan colored layer, and a yellow colored layer.

In a case where the photosensitive composition of the embodiment of the present invention is used as a color filter in applications for a liquid crystal display device, the voltage holding ratio of a liquid crystal display element comprising a color filter is preferably 70% or more, and more preferably 90% or more. Known means for obtaining a high voltage holding ratio can be incorporated as appropriate, and examples of typical means include use of high-purity materials (for example, reduction in ionic impurities) and control of the amount of acidic functional groups in a composition. The voltage holding ratio can be measured by, for example, the methods described in paragraph 0243 of JP2011-008004A and paragraphs 0123 to 0129 of JP2012-224847A.

<Method for Preparing Photosensitive Composition>

The photosensitive composition of the embodiment of the present invention can be prepared by mixing the above-mentioned components. In the preparation of the photosensitive composition, all the components may be dissolved and/or dispersed at the same time in a solvent to prepare the photosensitive composition, or the respective components may be appropriately left in two or more solutions or dispersion liquids and mixed to prepare the photosensitive composition upon use (during coating), as desired.

Furthermore, in the preparation of the photosensitive composition, a process for dispersing the pigment is preferably included. In the process for dispersing the pigment, examples of a mechanical force that is used for dispersion of the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. Further, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center. Oct. 10, 1978”, and paragraph No. 0022 of JP2015-157893A can be suitably used. In addition, in the process for dispersing the pigment, a refining treatment of particles in a salt milling process may be performed. With regard to the materials, the equipment, the process conditions, and the like used in the salt milling process, reference can be made to, for example, the description in JP2015-194521A and JP2012-046629A.

It is preferable that in the preparation of the photosensitive composition, a composition formed by mixing the respective components is filtered through a filter for the purpose of removing foreign matters, reducing defects, or the like. As the filter, any filters that have been used in the related art for filtration use and the like may be used without particular limitation. Examples of the filter include filters formed of materials including, for example, a fluorine resin such as polytetrafluoroethylene (PTFE), a polyamide-based resin such as nylon (for example, nylon-6 and nylon-6,6), and a polyolefin resin (including a polyolefin resin having a high density and/or an ultrahigh molecular weight) such as polyethylene and polypropylene (PP). Among these materials, polypropylene (including a high-density polypropylene) and nylon are preferable.

The pore diameter of the filter is suitably approximately 0.01 to 7.0 pun, preferably approximately 0.01 to 3.0 μm, and more preferably approximately 0.05 to 0.5 μm.

In addition, a fibrous filter material is also preferably used as the filter. Examples of the fibrous filter material include a polypropylene fiber, a nylon fiber, and a glass fiber. Examples of a filter using the fibrous filter material include filter cartridges of SBP type series (SBP008 and the like), TPR type series (TPR002, TPR005, and the like), or SHPX type series (SHPX003 and the like), manufactured by Roki Techno Co., Ltd.

In a case of using a filter, different filters may be combined. Here, the filtration with each of the filters may be performed once or may be performed twice or more times.

For example, filters having different pore diameters within the above-mentioned range may be combined. With regard to the pore diameter of the filter herein, reference can be made to nominal values of filter manufacturers. A commercially available filter may be selected from, for example, various filters provided by Nihon Pall Corporation (DFA4201NXEY and the like), Toyo Roshi Kaisha., Ltd., Nihon Entegris K. K (formerly Nippon Microlith Co., Ltd.), Kitz Micro Filter Corporation, and the like.

In addition, the filtration through the first filter may be performed with only a dispersion liquid, the other components may be mixed therewith, and then the filtration through the second filter may be performed. As the second filter, a filter formed of the same material as that of the first filter, or the like can be used.

<Cured Film>

The cured film of an embodiment of the present invention is a cured film obtained from the above-mentioned photosensitive composition of the embodiment of the present invention. The cured film of the embodiment of the present invention can be preferably used as a colored layer of a color filter.

The film thickness of the cured film can be appropriately adjusted depending on purposes. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

<Color Filter>

Next, the color filter of an embodiment of the present invention will be described.

The color filter of the embodiment of the present invention has the above-mentioned cured film of the embodiment of the present invention. In the color filter of the embodiment of the present invention, the film thickness of the cured film can be appropriately adjusted depending on the purposes. The film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more. The color filter of the embodiment of the present invention can be used for a solid-state imaging element such as a charge coupled device (CCD) and a complementary metal-oxide semiconductor (CMOS), an image display device, or the like.

<Pattern Forming Method>

Next, a pattern forming method using the photosensitive composition of the embodiment of the present invention will be described. The pattern forming method includes a step of forming a photosensitive composition layer on a support using the photosensitive composition of the embodiment of the present invention, and a step of forming a pattern onto the photosensitive composition layer by photolithography or a dry etching method.

Pattern formation by the photolithography preferably includes a step of forming a photosensitive composition layer on a support using the photosensitive composition, a step of patternwise exposing the photosensitive composition layer, and a step of removing unexposed areas by development to form a pattern. A step of baking the photosensitive composition layer (pre-baking step) and a step of baking the developed pattern (post-baking step) may be provided, as desired. Further, pattern formation by a dry etching method preferably includes a step of forming a photosensitive composition layer on a support using the photosensitive composition, a step of curing the photosensitive composition layer to form a cured product layer, a step of forming a photoresist layer on the cured product layer, a step of performing exposure and development to pattern the photoresist layer, thereby obtaining a resist pattern, and a step of dry etching the cured product layer using the resist pattern as an etching mask to form a pattern. Hereinafter, the respective steps will be described.

<<Step of Forming Coloring Composition Layer>>

In the step of forming a photosensitive composition layer, the photosensitive composition layer is formed on a support, using the photosensitive composition.

The support is not particularly limited, and can be appropriately selected depending on applications. Examples of the support include a glass substrate, a substrate for a solid-state imaging element, on which a solid-state imaging element (light-receiving element) such as a CCD and a CMOS is provided, and a silicon substrate. Further, an undercoat layer may be provided on the support, as desired, so as to improve adhesion to a layer above the support, to prevent diffusion of materials, or to flatten a surface of the substrate.

As a method for applying the photosensitive composition onto the support, various coating methods such as slit coating, an ink jet method, spin coating, cast coating, roll coating, and a screen printing method can be used.

The photosensitive composition layer formed on the support may be dried (pre-baked). In a case of forming a pattern by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. By setting the pre-baking temperature to 150° C. or lower, these characteristics can be more effectively maintained in a case of a configuration in which a photo-electric conversion film of an image sensor is formed of organic materials. The pre-baking time is preferably 10 seconds to 300 seconds, more preferably 40 to 250 seconds, and still more preferably 80 to 220 seconds. Drying can be performed using a hot plate, an oven, or the like.

(Case of Forming Pattern by Photolithography)

<<Exposing Step>>

Next, the photosensitive composition layer formed on the support is patternwise exposed (exposing step). For example, the photosensitive composition layer can be subjected to patternwise exposure by performing exposure using an exposure device such as a stepper through a mask having a predetermined mask pattern. Thus, the exposed portion can be cured. As the radiation (light) which can be used during the exposure, ultraviolet rays such as g-rays and i-rays (particularly preferably i-rays) are preferably used. The irradiation dose (exposure dose) is, for example, preferably 0.03 to 2.5 J/cm², and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. Further, the exposure illuminance can be appropriately set, and can be usually selected from a range of 1,000 W/m² to 100,000 W/m² (for example, 5.000 W/m², 15,000 W/m², or 35,000 W/m²). Appropriate conditions of each of the oxygen concentration and the illuminance of exposure energy may be combined, and for example, a combination of the oxygen concentration of 10% by volume and the illuminance of 10,000 W/m², a combination of the oxygen concentration of 35% by volume and the illuminance of 20,000 W/m², or the like is available.

<<Developing Step>>

Next, the unexposed areas are removed by development to form a pattern. The removal of the unexposed areas by development can be carried out using a developer. Thus, the photosensitive composition layer of the unexposed areas in the exposing step is eluted into the developer, and as a result, only a photocured portion remains.

As the developer, an organic alkali developer causing no damage on the underlying solid-state imaging element, circuit, or the like is preferable.

The temperature of the developer is preferably for example, 20° C. to 30° C., and the development time is preferably 20 to 180 seconds. Further, in order to improve residue removing properties, a step of removing the developer by shaking per 60 seconds and supplying a fresh developer may be repeated multiple times.

As the developer, an aqueous alkaline solution obtained by diluting an alkali agent with pure water is preferably used. Examples of the alkali agent include organic alkaline compounds such as aqueous ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. The concentration of the alkali agent in the aqueous alkaline solution is preferably 0.001% to 10% by mass, and more preferably 0.01% to 1% by mass. Moreover, the developer may further include a surfactant. Examples of the surfactant include the surfactants described as the above-mentioned photosensitive composition, and the surfactant is preferably a nonionic surfactant. The developer may be first produced as a concentrated liquid and then diluted to a concentration required upon from the viewpoints of transportation, storage, and the like. The dilution ratio is not particularly limited, and can be set to, for example, a range of 1.5 to 100 times. In addition, in a case where a developer including such an aqueous alkaline solution is used, it is preferable to perform washing (rinsing) with pure water after development.

After the development, a heating treatment (post-baking) can also be performed after carrying out drying. The post-baking is a heating treatment after development so as to complete the curing of the film. In a case of performing the post-baking, the post-baking temperature is preferably, for example, 100° C. to 240° C. From the viewpoint of curing of the film, the post-baking temperature is more preferably 200° C. to 230° C. The Young's modulus of the film after post-baking is preferably 0.5 to 20 GPa, and more preferably 2.5 to 15 GPa. In addition, in a case where a support on which the cured film is formed includes an organic electroluminescence (organic EL) element, an image sensor having a photo-electric conversion film constituted with organic materials, or the like, the post-baking temperature is preferably 150° C. or lower, more preferably 120° C. or lower, still more preferably 100° C. or lower, and particularly preferably 90° C. or lower. The lower limit can be set to, for example, 50° C. or higher. The post-baking can be performed continuously or batchwise by using a heating means such as a hot plate, a convection oven (hot-air circulating dryer), and a high-frequency heater so that the film after development (cured film) satisfies the conditions.

The cured film preferably has high flatness. Specifically, the surface roughness Ra is preferably 100 nm or less, more preferably 40 nm or less, and still more preferably 15 nm or less. The lower limit is not specified, but is preferably, for example 0.1 nm or more. The surface roughness can be measured, for example, using an atomic force microscope (AFM) Dimension 3100 manufactured by Veeco Instruments, Inc.

In addition, the contact angle of water on the cured film can be appropriately set to a preferred value, but is typically in the range of 50° to 110°. The contact angle can be measured, for example, using a contact angle meter CV-DT.A Model (manufactured by Kyowa Interface Science Co., Ltd.).

A higher volume resistivity value of each pattern (pixel) is desired. Specifically, the volume resistivity value of the pixel is preferably 10⁹ Ω·cm or more, and more preferably 10¹¹ Ω·cm or more. The upper limit is not defined, but is, for example, preferably 10¹⁴ Ω·cm or less. The volume resistivity value of the pixel can be measured, for example, using an ultra high resistance meter 5410 (manufactured by Advantest Corporation).

(Case of Forming Pattern by Dry Etching Method)

Pattern formation by a dry etching method can be performed by, for example, a method in which a photosensitive composition layer formed by applying a photosensitive composition onto a support or the like is cured to form a cured product layer, a patterned photoresist layer is then formed on the cured product layer, and the cured product layer is dry-etched with an etching gas, using the patterned photoresist layer as a mask.

As for the photoresist layer, it is preferable that a positive tone or negative tone radiation-sensitive composition is applied onto a cured product layer, and dried to form a photoresist layer. As the radiation-sensitive composition used for formation of the photoresist layer, a positive tone radiation-sensitive composition is preferably used. As the positive tone radiation-sensitive composition, a radiation-sensitive composition which is sensitive to radiations such as far ultraviolet-rays including ultraviolet rays (g-rays, h-rays, and i-rays), KrF-rays, ArF-rays, and the like, electron beams, ion beams, and X-rays is preferable. The above-mentioned positive tone radiation-sensitive composition is preferably a radiation-sensitive composition which is sensitive to KrF-rays. ArF-rays, i-rays, or X-rays, and from the viewpoint of micromachining, it is more preferably a radiation-sensitive composition which is sensitive to KrF-rays. As the positive tone photosensitive resin composition, the positive tone resist compositions described in JP2009-237173A or JP2010-134283A is suitably used. In the formation of a photoresist layer, an exposing step with the radiation-sensitive composition is preferably performed with KrF-rays, ArF-rays, i-rays, X-rays, or the like, more preferably performed with KrF-rays, ArF-rays, X-rays, or the like, and still more preferably performed with KrF-rays.

<Solid-State Imaging Element>

The solid-state imaging element of an embodiment of the present invention has the above-mentioned color filter of the embodiment of the present invention. The configuration of the solid-state imaging element of the embodiment of the present invention is not particularly limited as long as the solid-state imaging element is configured to include the color filter in the embodiment of the present invention and function as a solid-state imaging element. However, examples thereof include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiode, on the photodiodes and the transfer electrodes; have a device-protective film formed of silicon nitride or the like, which is formed to coat the entire surface of the light-shielding film and the light receiving portion of the photodiodes, on the light-shielding film; and have a color filter on the device-protective film. In addition, the solid-state imaging element may also be configured, for example, such that it has a light collecting means (for example, a microlens, which is the same hereinafter) on a device-protective film under a color filter (a side closer to the substrate), or has a light collecting means on a color filter. Further, the color filter may have a structure in which a cured film forming each colored pixel is embedded in, for example, a space partitioned in a lattice shape by a partition wall. The partition wall in this case preferably has a low refractive index for each colored pixel. Examples of an imaging device having such a structure include the devices described in JP2012-227478A and JP2014-179577A. An imaging device comprising the solid-state imaging element of the embodiment of the present invention can also be used as a vehicle camera or a monitoring camera, in addition to a digital camera or electronic equipment (mobile phones or the like) having an imaging function.

<Image Display Device>

The color filter of the embodiment of the present invention can be used for an image display device such as a liquid crystal display device and an organic electroluminescence display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989)”, and the like. In addition, the liquid crystal display device is described in, for example, “Liquid Crystal Display Technology for Next Generation (edited by Tatsuo Uchida. Kogyo Chosakai Publishing Co., Ltd., published in 1989)”. The liquid crystal display device to which the present invention can be applied is not particularly limited, and can be applied to, for example, liquid crystal display devices employing various systems described in the “Liquid Crystal Display Technology for Next Generation”.

### Examples

Hereinbelow, the present invention will be described in more detail with reference to Examples. The materials, the amounts of materials used, the proportions, the treatment details, the treatment procedure, or the like shown in the Examples below may be modified if appropriate as long as the modifications do not depart from the spirit of the present invention. Therefore, the scope of the present invention is not limited to the specific Examples shown below. In addition, “parts” and “%” are on a mass basis unless otherwise specified.

<Measurement of Weight-Average Molecular Weight>

The weight-average molecular weight of a compound A and a resin was measured by means of gel permeation chromatography (GPC) under the following condition.

Types of columns: Columns formed by connection of TOSOH TSKgel Super HZM-H, TOSOH TSKgel Super HZ4000, and TOSOH TSKgel Super HZ2000

Developing solvent: Tetrahydrofuran

Column temperature: 40° C.

Flow amount (amount of a sample to be injected): 1.0 μL (sample concentration: 0.1% by mass)

Device name: HLC-8220GPC manufactured by Tosoh Corporation

Detector: Refractive index (RI) detector

Calibration curve base resin: Polystyrene resin

<Method for Measuring Acid Value>

The acid values of the compound A and the resin are each a representation of the mass of potassium hydroxide required to neutralize acidic components per gram of the solid content. The acid values of the compound A and the resin were measured as follows. That is, a measurement sample was dissolved in a mixed solvent of tetrahydrofuran/water=9/1 (mass ratio), and the obtained solution was titration by neutralization with a 0.1-mol/L aqueous sodium hydroxide solution, using a potentiometric titrator (trade name: AT-510, manufactured by Kyoto Denshi K. K.) at 25° C. By using the inflection point in a titration pH curve as a titration end point, an acid value was calculated by the following equation.

A=56.11×Vs×0.5×f/w

A: Acid value (mgKOH/g)

Vs: Use amount (mL) of a 0.1-mol/L aqueous sodium hydroxide solution required for titration

f: Titer of a 0.1-mol/L aqueous sodium hydroxide solution

w: Mass (g) (in terms of a solid content) of a measurement sample

<Measurement of C═C Value>

The C═C value of the compound A represents a molar amount of the C═C group per gram of the solid content of the compound A, and a low-molecular-weight component (a) of a C═C group site (for example, methacrylic acid in P-1 and acrylic acid in P-2 shown in specific examples of the compound A) was extracted from the compound A by an alkali treatment, a content thereof was measured by high performance liquid chromatography (HPLC), and a C═C value was calculated from the following formula, based on the measured value. Specifically, 0.1 g of a measured sample was dissolved in a tetrahydrofuran/methanol mixed liquid (50 mL/15 mL), and 10 mL of a 4-mol/L aqueous sodium hydroxide solution was added thereto to perform a reaction at 40° C. for 2 hours. The reaction liquid was neutralized with 10.2 mL of a 4-mol/L aqueous methanesulfonic acid solution, and then a mixed liquid formed by addition of 5 mL of ion exchange water and 2 mL of methanol was transferred to a 100-mL volumetric flask and filled up with methanol to prepare a HPLC measurement sample, which was measured under the following conditions. Further, the content of the low-molecular-weight component (a) was calculated from a calibration curve of the low-molecular-weight component (a) which had been separately, and a C═C value was calculated using the following equation.

(Equation for Calculation of C═C Value)

C═C Value [mmol/g]=(Content [ppm] of low-molecular-weight component (a)/Molecular weight [g/mol] of low-molecular-weight component (a))/(Weighed value [g] of liquid preparation polymer×(Concentration [%] of solid content of polymer solution/100)×10)

(Conditions for HPLC Measurement)

Measurement equipment: Agilent-1200

Columns: Synergi 4u Polar-RP 80A manufactured by Phenomenex Inc., 250 mm×4.60 mm (inner diameter)+guard column

Column temperature: 40° C.

Analysis time: 15 minutes

Flow rate: 1.0 mL/min (maximum liquid-feeding pressure: 182 bar)

Injection volume: 5 μl

Detection wavelength: 210 nm

Eluent: Tetrahydrofuran (for stabilizer-free HPLC)/buffer solution (aqueous ion exchange solution containing 0.2% by volume of phosphoric acid and 0.2%0/by volume of triethylamine)=55/45 (% by volume)

<Preparation of Dispersion Liquid>

The components described in the following table were mixed, then 230 parts by mass of zirconia beads having a diameter of 0.3 mm added thereto, and the mixture was subjected to a dispersion treatment for 5 hours, using a paint shaker. Subsequently, the zirconia beads were separated by filtration to prepare a dispersion liquid.

TABLE 8

| | Color material | | Pigment derivative | | | | | |
|---|---|---|---|---|---|---|---|---|
| | | Parts | | Parts | Dispersant | | Solvent | |
| | Type | by mass | Type | by mass | Type | Parts by mass | Type | Parts by mass |
| Pigment dispersion liquid 1 | PR254 | 11.57 | Derivative 1 | 1.39 | P-6 | 4.54 | PGMEA | 82.50 |
| Pigment dispersion liquid 2 | PY139 | 11.57 | Derivative 1 | 1.39 | P-15 | 4.54 | PGMEA | 82.50 |
| Pigment dispersion liquid 3 | PR254 | 11.57 | Derivative 1 | 1.39 | P-8 | 3.24 | PGMEA | 83.80 |
| Pigment dispersion liquid 4 | PR254 | 7.98 | Derivative 1 | 1.39 | P-7 | 3.24 | PGMEA | 83.80 |
| | PY139 | 3.59 | | | | | | |
| Pigment dispersion liquid 5 | PY139 | 11.57 | Derivative 1 | 1.39 | P-8 | 3.24 | PGMEA | 83.80 |
| Pigment dispersion liquid 6 | PB15:6 | 10.2 | — | — | P-22 | 5.38 | PGMEA | 81.82 |
| | PV23 | 2.6 | | | | | | |
| Pigment dispersion liquid 7 | PB15:6 | 10.2 | — | — | P-8 | 3.20 | PGMEA | 84.00 |
| | PV23 | 2.6 | | | | | | |
| Pigment dispersion liquid 8 | PG58 | 9.2 | Derivative 1 | 1.2 | P-16 | 4.95 | PGMEA | 82.35 |
| | PY185 | 2.3 | | | | | | |
| Pigment dispersion liquid 9 | PG58 | 9.2 | Derivative 1 | 1.2 | P-15 | 4.11 | PGMEA | 84.12 |
| | PY185 | 2.3 | | | | | | |
| Pigment dispersion liquid 10 | PR254 | 7.98 | Derivative 1 | 1.39 | P-1 | 3.24 | PGMEA | 83.80 |
| | PY139 | 3.59 | | | | | | |
| Pigment dispersion liquid 11 | PR254 | 7.98 | Derivative 1 | 1.39 | P-6 | 3.24 | PGMEA | 83.80 |
| | PY139 | 3.59 | | | | | | |
| Pigment dispersion liquid 12 | PR264 | 7.98 | Derivative 1 | 1.39 | P-8 | 3.24 | PGMEA | 83.80 |
| | PY139 | 3.59 | | | | | | |
| Pigment dispersion liquid 13 | PR254 | 7.98 | Derivative 1 | 1.39 | P-24 | 3.24 | PGMEA | 83.80 |
| | PY139 | 3.59 | | | | | | |
| Pigment dispersion liquid 14 | PR254 | 11.57 | Derivative 1 | 1.39 | Dispersant 1 | 4.54 | PGMEA | 82.50 |
| Pigment dispersion liquid 15 | PY139 | 11.57 | Derivative 1 | 1.39 | Dispersant 2 | 4.54 | PGMEA | 82.50 |
| Pigment dispersion liquid 16 | PG58 | 9.2 | Derivative 1 | 1.2 | Dispersant 2 | 4.95 | PGMEA | 82.35 |
| | PY185 | 2.3 | | | | | | |
| Pigment dispersion liquid 17 | PB15:6 | 10.2 | — | — | Dispersant 1 | 5.38 | PGMEA | 81.82 |
| | PV23 | 2.6 | | | | | | |
| Pigment dispersion liquid 18 | PG36 | 12.1 | — | — | P-2 | 5.69 | PGMEA | 85.40 |
| | PY150 | 1.8 | | | | | | |
| Pigment dispersion liquid 19 | PB15:6 | 12.02 | — | — | P-20 | 4.54 | PGMEA | 83.44 |
| Pigment dispersion liquid 20 | PR254 | 8.59 | Derivative 1 | 0.5 | P-22 | 3.24 | PGMEA | 83.80 |
| | PY139 | 3.87 | | | | | | |
| Pigment dispersion liquid 21 | PG58 | 9.7 | Derivative 1 | 0.5 | P-16 | 4.32 | PGMEA | 82.98 |
| | PY185 | 2.5 | | | | | | |
| Pigment dispersion liquid 22 | PR254 | 7.98 | Derivative 1 | 1.39 | D2 | 4.54 | PGMEA | 82.50 |
| | PY139 | 3.59 | | | | | | |

<Preparation of Photosensitive Composition>

The components described in the following table were mixed to prepare a photosensitive composition. Further, the value of the concentration of the color material in the following table is a value of the content of the color material in the total solid content of the photosensitive composition. In addition, the value of the content of the compound A is a value of the content of the compound with a weight-average molecular weight of 3,000 or more having an ethylenically unsaturated group in the total mass of the compound having an ethylenically unsaturated group.

TABLE 9

| | | | Color | | | | Polymerizable | | | |
|---|---|---|---|---|---|---|---|---|---|---|
| | | | material | | Resin | | compound | | Photopolymerization | |
| | Pigment dispersion liquid | | | Parts by | | Parts by | | Parts by | initiator | |
| | Type | Parts by mass | Type | mass | Type | mass | Type | mass | Type | Parts by mass |
| Example 1 | Pigment dispersion liquid 1 | 42.23 | | | D2 | 1.02 | E2 | 0.86 | F1 | 0.45 |
| | Pigment dispersion liquid 2 | 19.00 | | | | | | | | |
| Example 2 | Pigment dispersion liquid 4 | 71.76 | | | | | | | F1 | 0.37 |
| Example 3 | Pigment dispersion liquid 3 | 41.24 | | | | | | | F2 | 0.31 |
| | Pigment dispersion liquid 5 | 18.56 | | | | | | | | |
| Example 4 | Pigment dispersion liquid 8 | 71.54 | | | D1 | 1.15 | E1 | 0.94 | F1 | 0.76 |
| Example 5 | Pigment dispersion liquid 9 | 71.70 | | | D2 | 0.49 | | | F3 | 0.41 |
| Example 6 | Pigment dispersion liquid 6 | 49.00 | | | D1 | 1.74 | E1 | 0.99 | F1 | 0.67 |
| Example 7 | Pigment dispersion liquid 7 | 60.08 | | | D1 | 1.69 | | | F3 | 0.53 |
| Example 8 | Pigment dispersion liquid 10 | 71.76 | | | | | | | F1 | 0.37 |
| Example 9 | Pigment dispersion liquid 11 | 71.76 | | | | | | | F2 | 0.37 |
| Example 10 | Pigment dispersion liquid 12 | 71.76 | | | | | | | F1 | 0.37 |
| Example 11 | Pigment dispersion liquid 13 | 71.76 | | | | | | | F1 | 0.37 |
| Example 12 | Pigment dispersion liquid 18 | 79.97 | | | D2 | 1.57 | | | F1 | 0.51 |
| Example 13 | Pigment dispersion liquid 19 | 47.39 | B-1 | 3.00 | | | | | F2 | 0.34 |
| Example 14 | Pigment dispersion liquid 19 | 47.39 | B-2 | 3.00 | | | | | F2 | 0.34 |
| Example 15 | Pigment dispersion liquid 19 | 47.39 | B-3 | 3.00 | | | | | F2 | 0.34 |
| Example 16 | Pigment dispersion liquid 19 | 47.39 | B-4 | 3.00 | | | | | F2 | 0.34 |
| Example 17 | Pigment dispersion liquid 20 | 71.76 | | | | | | | F1 | 0.37 |
| Example 18 | Pigment dispersion liquid 21 | 72.19 | | | | | | | F3 | 0.41 |
| Example 19 | Pigment dispersion liquid 22 | 61.23 | | | D2 | 1.02 | E2 | 0.86 | F1 | 0.45 |
| Comparative | Pigment dispersion liquid 14 | 42.23 | | | D2 | 1.02 | E2 | 0.86 | F2 | 0.45 |
| Example 1 | Pigment dispersion liquid 15 | 19.00 | | | | | | | | |
| Comparative | Pigment dispersion liquid 16 | 77.87 | | | D2 | 0.49 | E3 | 1.78 | F2 | 0.83 |
| Example 2 | | | | | | | | | | |
| Comparative | Pigment dispersion liquid 17 | 41.00 | | | D1 | 0.79 | E3 | 2.09 | F2 | 1.40 |
| Example 3 | | | | | | | | | | |

| | | | | | Polymerization | | | | | |
|---|---|---|---|---|---|---|---|---|---|---|
| | | | Surfactant | | inhibitor | | Solvent | | Color material | Content (% by |
| | Additive | | | Parts by | | Parts by | | Parts by | concentration | mass) of |
| | Type | Parts by mass | Type | mass | Type | mass | Type | mass | (% by mass) | compound A |
| Example 1 | | | H1 | 4.17 | I1 | 0.0006 | PGMEA | 32.27 | 54% | 82% |
| Example 2 | | | H1 | 3.34 | I1 | 0.0006 | PGMEA | 24.54 | 69% | 100% |
| Example 3 | | | H1 | 3.34 | I1 | 0.0006 | PGMEA | 36.56 | 69% | 100% |
| Example 4 | I1 | 0.316 | H1 | 4.17 | I1 | 0.0006 | PGMEA | 21.13 | 52% | 79% |
| Example 5 | | | H1 | 4.17 | I1 | 0.0006 | PGMEA | 23.24 | 63% | 100% |
| Example 6 | | | H1 | 4.17 | I1 | 0.0006 | PGMEA | 43.43 | 51% | 73% |
| Example 7 | | | H1 | 4.17 | I1 | 0.0006 | PGMEA | 33.53 | 65% | 100% |
| Example 8 | | | H1 | 3.34 | I1 | 0.0006 | PGMEA | 24.54 | 69% | 100% |
| Example 9 | | | H1 | 3.34 | I1 | 0.0006 | PGMEA | 24.54 | 69% | 100% |
| Example 10 | | | H1 | 3.34 | I1 | 0.0006 | PGMEA | 24.54 | 69% | 100% |
| Example 11 | | | H1 | 3.34 | I1 | 0.0006 | PGMEA | 24.54 | 69% | 100% |
| Example 12 | | | H1 | 4.17 | I1 | 0.0006 | PGMEA | 13.54 | 64% | 100% |
| Example 13 | | | H1 | 4.17 | I1 | 0.0006 | CHN | 45.10 | 77% | 100% |
| Example 14 | | | H1 | 4.17 | I1 | 0.0006 | CHN | 45.10 | 77% | 100% |
| Example 15 | | | H1 | 4.17 | I1 | 0.0006 | CHN | 45.10 | 77% | 100% |
| Example 16 | | | H1 | 4.17 | I1 | 0.0006 | CHN | 45.10 | 77% | 100% |
| Example 17 | | | H1 | 3.34 | I1 | 0.0006 | PGMEA | 24.54 | 77% | 100% |
| Example 18 | | | H1 | 4.17 | I1 | 0.0006 | PGMEA | 23.24 | 71% | 100% |
| Example 19 | | | H1 | 4.17 | I1 | 0.0006 | PGMEA | 32.27 | 54% | 82% |
| Comparative | | | H1 | 4.17 | I1 | 0.0006 | PGMEA | 32.27 | 54% | 54% |
| Example 1 | | | | | | | | | | |
| Comparative | | | H1 | 4.17 | I1 | 0.0004 | PGMEA | 14.51 | 53% | 22% |
| Example 2 | | | | | | | | | | |
| Comparative | | | H1 | 4.17 | I1 | 0.0004 | PGMEA | 50.54 | 45% | 0% |
| Example 3 | | | | | | | | | | |

The components described in the following table are as follows.

(Color Material)

PR254: C. I. Pigment Red 254

PR264: C. I. Pigment Red 264

PY139: C. I. Pigment Yellow 139

PY150: C. I. Pigment Yellow 150

PY185: C. I. Pigment Yellow 185

PB15: 6: C. I. Pigment Blue 15:6

PV23: C. I. Pigment Violet 23

PG36: C. I. Pigment Green 36

PG58: C. I. Pigment Green 58

B-1: Compound having the following structure (dye multimer, Mw-12.000, and the numerical value described together with the repeating unit of the main chain is a molar ratio.)

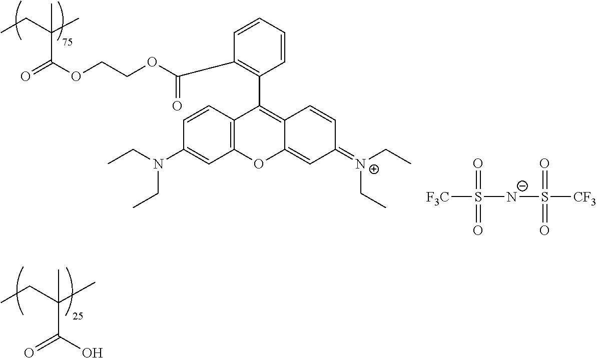

B-2: Compound having the following structure (dye multimer, Mw-13,200, and the numerical value described together with the repeating unit of the main chain is a molar ratio.)

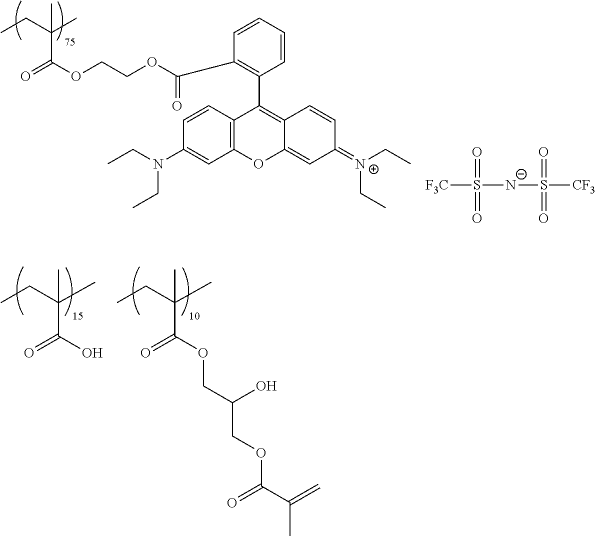

B-3: Compound having the following structure (dye multimer, Mw-13.200, and the numerical value described together with the repeating unit of the main chain is a molar ratio.)

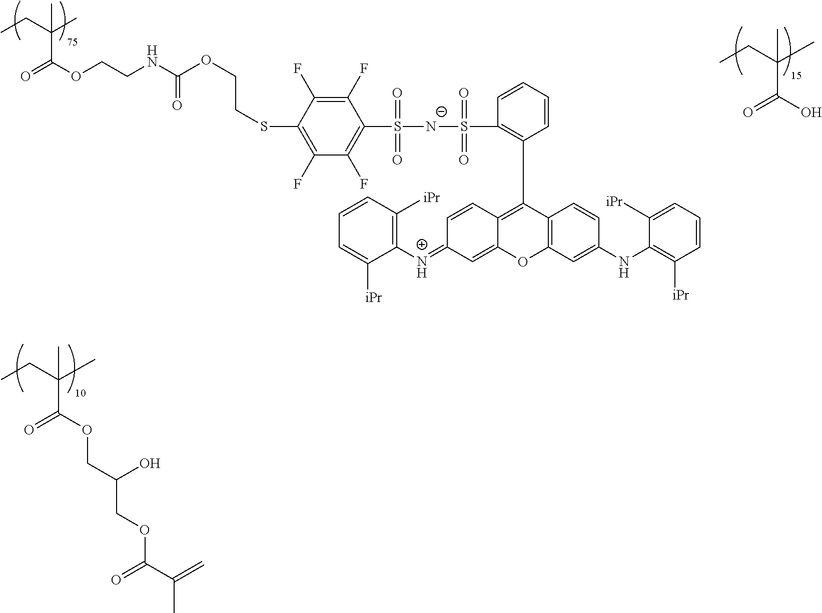

B-4: Compound having the following structure (dye multimer (molar ratio of a xanthene skeleton/methacrylic acid/an adduct of methacrylic acid and glycidyl methacrylate=5/6/6, and an average number of repeating units derived from methacrylic acid and repeating units derived from the adduct of methacrylic acid and glycidyl methacrylate methacrylic acid is 12), Mw=11,600)

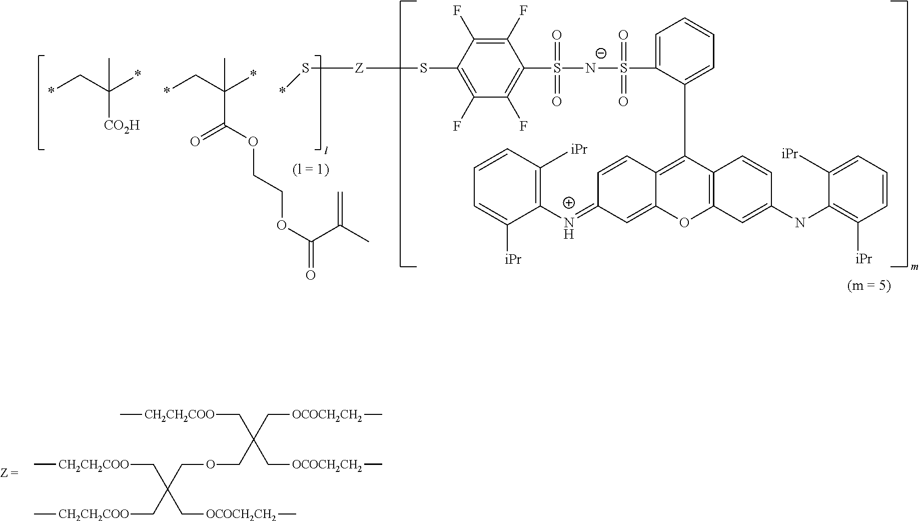

(Pigment Derivative)

Derivative 1: Compound having the following structure.

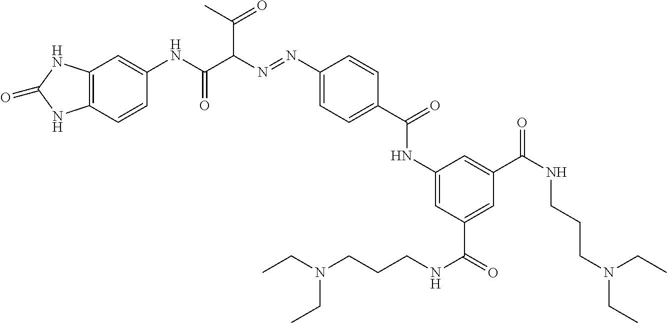 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

(Dispersants. Resins)

P-1, P-2, P-6, P-7, P-8, P-15, P-16, P-20, P-22, and P-24: P-1, P-2, P-6, P-7, P-8, P-15, P-16, P-22, and P-24 mentioned in the specific examples of the above-mentioned compound A. These are all compounds having a weight-average molecular weight of 3,000 or more, including a repeating unit having an ethylenically unsaturated group and a repeating unit having a graft chain.

Dispersant 1: Resin having the following structure. The numerical value described together with the main chain is a molar ratio and the numerical value described together with the side chain is the number of repeating units. Mw=20,000.

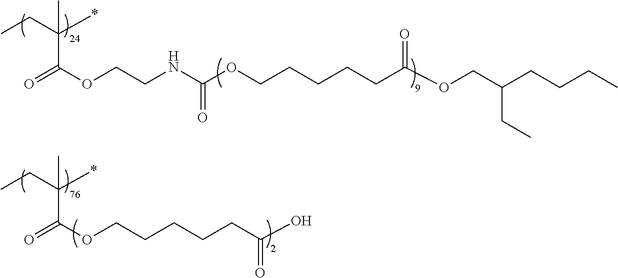

Dispersant 2: Resin having the following structure. The numerical value described together with the main chain is a molar ratio, and the numerical value described together with the side chain is the number of repeating units. Mw=24,000.

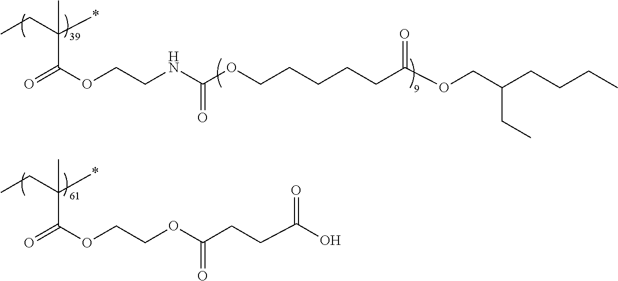

D1: Resin having the following structure. The numerical value described together with the main chain is a molar ratio. Mw=30,000.

D2: Resin having the following structure. The numerical value described together with the main chain is a molar ratio. Mw-11,000. D2 is a compound with a weight-average molecular weight of 3,000 or more, including a repeating unit having an ethylenically unsaturated group.

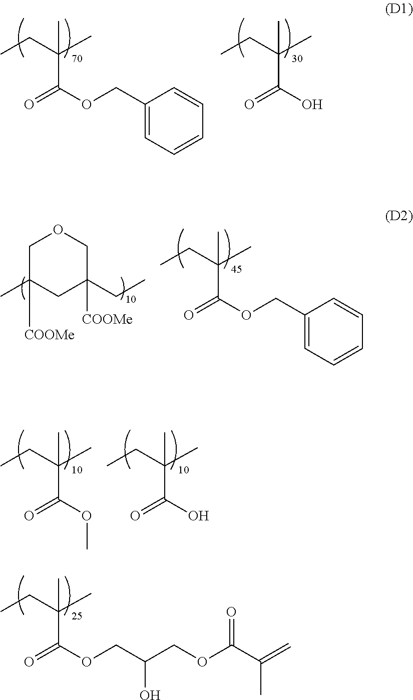

(Polymerizable Compound)

E1: KAYARAD DPHA (manufactured by Nippon Kayaku Co., Ltd.)

E2: NK ESTER A-TMMT (manufactured by Shin-Nakamura Chemical Co., Ltd.) (molecular weight: 352)

E3: NK ESTER A-DPH-12E (manufactured by Shin-Nakamura Chemical Co., Ltd.)

Any of the polymerizable compounds E1 to E3 are compounds with a molecular weight of less than 3,000 having an ethylenically unsaturated group.

(Photopolymerization Initiator)

F1: IRGACURE OXE02 (manufactured by BASF)

F2: IRGACURE 369 (manufactured by BASF)

F3: IRGACURE OXE01 (manufactured by BASF)

(Surfactant)

H1: 1%-by-mass PGMEA solution of the following mixture (Mw=14,000). In the following formulae, % representing the ratio of the repeating units is % by mole.

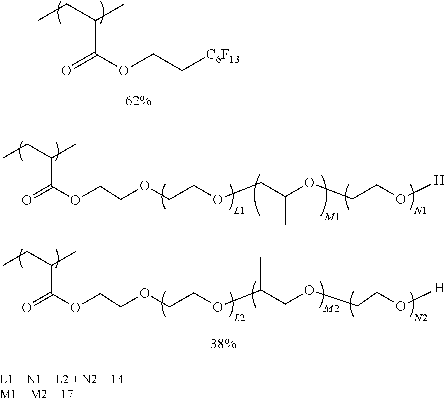

(Polymerization Inhibitor)

I1: p-Methoxyphenol

(Additive)

J1: EHPE-3150 (manufactured by Daicel Chemical Industries, Ltd., epoxy compound)

(Solvent)

PGMEA: Propylene glycol monomethyl ether acetate

CHN: Cyclohexanone

<Evaluation of Color Unevenness>

CT-4000 (manufactured by Fujifilm Electronic Materials Co., Ltd.) was applied onto a glass substrate such that the film thickness reached 0.1 μm by a spin coating method, and heated at 220° C. for 1 hour using a hot plate to form an underlayer. Each of the photosensitive compositions was applied onto the glass substrate having the underlayer by a spin coating method and heated at 100° C. for 2 minutes using a hot plate to form a photosensitive composition layer having a film thickness described in the following table (hereinafter also simply referred to as a “composition layer”).

This composition layer was irradiated with light at a wavelength of 365 nm to perform exposure at 500 mJ/cm². Subsequently, the composition layer was post-baked at 220° C. for 300 seconds using a hot plate to form a film. Using the glass substrate having the film thereon (substrate for evaluation), a brightness distribution was analyzed by the following method, and the color unevenness was evaluated on the basis of the number of pixels having a deviation from a mean of ±10% or more.

A method for measuring the brightness distribution will be described. A substrate for evaluation was placed between an observation lens and a light source in an optical microscope, the observation lens was irradiated with light, and the transmitted light state was observed using an optical microscope MX-50 (manufactured by Olympus Corporation) having a digital camera installed therein. Imaging of the film surface was carried out on five regions arbitrarily selected. The brightness of the imaged image was stored by digitizing a concentration distribution of 256 gradations ranging from 0 to 255. The brightness distribution was analyzed from the image, and the color unevenness was evaluated with the number of pixels having a deviation from a mean of more than ±10%. The evaluation standard was as follows.

5: The number of pixels having a deviation from a mean of more than ±10 is 1,000 or less.

4: The number of pixels having a deviation from a mean of more than ±10 is more than 1,000 and 3,000 or less.

3: The number of pixels having a deviation from a mean of more than ±10 is more than 3,000 and 5,000 or less.

2: The number of pixels having a deviation from a mean of more than ±10 is more than 5.000 and 15,000 or less.

1: The number of pixels having a deviation from a mean of more than ±10 is more than 15,000.

<Evaluation of Adhesiveness>

CT-4000 (manufactured by Fujifilm Electronic Materials Co., Ltd.) was applied onto a silicon wafer such that the film thickness reached 0.1 μm by a spin coating method, and heated at 220° C. for 1 hour using a hot plate to form an underlayer. Each of the photosensitive compositions was applied onto the silicon wafer having the underlayer by a spin coating method, and heated at 100° C. for 2 minutes using a hot plate to form a composition layer having a film thickness described in the following table.

This composition layer was exposed at an exposure dose of 500 mJ/cm² by irradiation of light at a wavelength of 365 nm through a mask pattern in which square pixels were arranged in a 4 mm×3 mm region on each substrate in 1.1 μm at one side, using an i-ray stepper FPA-3000i5+ (manufactured by Canon Inc.).

The expose composition layer was puddle-developed at 23° C. for 60 seconds using a 0.3%-by-mass aqueous tetramethylammonium hydroxide solution. Thereafter, rinsing was performed with water by spin shower, and washing with pure water was further performed. Subsequently, water droplets were blown out with high-pressure air and the silicon wafer was naturally dried ad then post-baked at 220° C. for 300 seconds using a hot plate to form a pattern. The obtained pattern was observed using an optical microscope to count the adhered patterns in all the patterns. The adhesiveness was evaluated based on the following evaluation standard.

5: All of the patterns are adhered.

4: A proportion of the adhered patterns is 90% or more and less than 100% of all the patterns.

3: A proportion of the adhered patterns is 80% or more and less than 90% of all the patterns.

2: A proportion of the adhered patterns is 70% or more and less than 80% of all the patterns.

1: A proportion of the adhered patterns is less than 70% of all the patterns.

TABLE 10

| | Film thickness | Evaluation | |
|---|---|---|---|
| | μm | Color unevenness | Adhesiveness |
| Example 1 | 0.5 | 3 | 3 |
| Example 2 | 0.4 | 5 | 5 |
| Example 3 | 0.4 | 4 | 4 |
| Example 4 | 0.5 | 5 | 5 |
| Example 5 | 0.4 | 4 | 4 |
| Example 6 | 0.5 | 5 | 4 |
| Example 7 | 0.4 | 5 | 5 |
| Example 8 | 0.4 | 3 | 2 |
| Example 9 | 0.4 | 3 | 3 |
| Example 10 | 0.4 | 4 | 4 |
| Example 11 | 0.4 | 2 | 3 |
| Example 12 | 0.4 | 5 | 5 |
| Example 13 | 0.4 | 5 | 5 |
| Example 14 | 0.4 | 5 | 5 |
| Example 15 | 0.4 | 5 | 5 |
| Example 16 | 0.4 | 5 | 5 |
| Example 17 | 0.4 | 5 | 5 |
| Example 18 | 0.4 | 5 | 5 |
| Example 19 | 0.5 | 2 | 2 |
| Comparative Example 1 | 0.5 | 1 | 1 |
| Comparative Example 2 | 0.5 | 1 | 1 |
| Comparative Example 3 | 0.5 | 1 | 1 |

As shown in the table, it was possible to produce a cured film having less color unevenness by using the photosensitive compositions of Examples. Furthermore, the cured film had excellent adhesiveness to the substrate. Incidentally, the cured films obtained from the photosensitive compositions of Examples 1 to 3 and 8 to 11, 17, and 19 had preferred spectral characteristics as a red colored layer. Further, the cured films obtained from the photosensitive compositions of Examples 4, 5, 12, and 18 had preferred spectral characteristics as a green coloring layer. Furthermore, the cured film obtained from the photosensitive compositions of Examples 6, 7, and 13 to 16 had preferred spectral characteristic as a blue coloring layer. In addition, in the photosensitive compositions of Examples 2, 3, 5, and 7 to 18, not including a polymerizable compound, it was possible to produce a cured film which was thinner and had excellent spectral characteristics as a color filter. These Examples were excellent from the viewpoint of lower profiles and suppressed crosstalk of the color filter.

What is claimed is:

1. A photosensitive composition comprising:
a compound having an ethylenically unsaturated group;
a color material; and
a photopolymerization initiator,
wherein a content of the color material is 50% by mass or more with respect to the total solid content of the photosensitive composition, and
a content of a compound A with a weight-average molecular weight of 3,000 or more having an ethylenically unsaturated group in the total mass of the compound having an ethylenically unsaturated group is 70% by mass or more.

2. The photosensitive composition according to claim 1,
wherein a content of the compound A in the total mass of the compound having an ethylenically unsaturated group is 90% by mass or more.

3. The photosensitive composition according to claim 1,
wherein the compound A includes a repeating unit having an ethylenically unsaturated group in a side chain.

4. The photosensitive composition according to claim 2,
wherein the compound A includes a repeating unit having an ethylenically unsaturated group in a side chain.

5. The photosensitive composition according to claim 3,
wherein the repeating unit having an ethylenically unsaturated group in a side chain has at least one group selected from a vinyl group, a vinyloxy group, an allyl group, a methallyl group, a (meth)acryloyl group, a styryl group, a cinnamoyl group, or a maleimido group in a side chain.

6. The photosensitive composition according to claim 4,
wherein the repeating unit having an ethylenically unsaturated group in a side chain has at least one group selected from a vinyl group, a vinyloxy group, an allyl group, a methallyl group, a (meth)acryloyl group, a styryl group, a cinnamoyl group, or a maleimido group in a side chain.

7. The photosensitive composition according to claim 1,
wherein the compound A further includes a repeating unit having a graft chain.

8. The photosensitive composition according to claim 2,
wherein the compound A further includes a repeating unit having a graft chain.

9. The photosensitive composition according to claim 1,
wherein the compound A includes a repeating unit having an ethylenically unsaturated group and a repeating unit having a graft chain.

10. The photosensitive composition according to claim 7,
wherein the graft chain includes at least one structure selected from a polyester structure, a polyether structure, a poly(meth)acryl structure, a polyurethane structure, a polyurea structure, or a polyamide structure.

11. The photosensitive composition according to claim 7,
wherein the graft chain includes a polyester structure.

12. The photosensitive composition according to claim 7,
wherein the weight-average molecular weight of the repeating unit having a graft chain is 1,000 or more.

13. The photosensitive composition according to claim 1,
wherein the compound A includes a repeating unit represented by Formula (A-1-1) and a repeating unit represented by Formula (A-1-2), 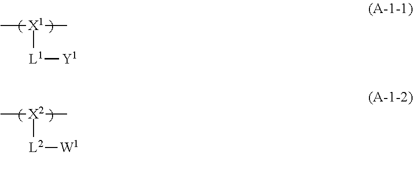
in Formula (A-1-1), X¹ represents a main chain of the repeating unit, L¹ represents a single bond or a divalent linking group, and Y¹ represents a group including an ethylenically unsaturated group, and
in Formula (A-1-2), X² represents a main chain of the repeating unit, L² represents a single bond or a divalent linking group, and W¹ represents a graft chain.

14. The photosensitive composition according to claim 1,
wherein the compound A further includes a repeating unit having an acid group.

15. The photosensitive composition according to claim 1,
wherein an amount of the ethylenically unsaturated group of the compound A is 0.2 to 5.0 mmol/g.

16. The photosensitive composition according to claim 1,
wherein an acid value of the compound A is 20 to 150 mgKOH/g.

17. A cured film obtained from the photosensitive composition according to claim 1.

18. A color filter comprising the cured film according to claim 17.

19. A solid-state imaging element comprising the cured film according to claim 17.

20. An image display device comprising the cured film according to claim 17.
